(19) United States
(12) Patent Application Publication
(10) Pub. No.: US 2013/0264913 A1
(43) Pub. Date: Oct. 10, 2013

(54) VIBRATOR ELEMENT, VIBRATION DEVICE AND ELECTRONIC APPARATUS

(71) Applicant: SEIKO EPSON CORPORATION, Tokyo (JP)

(72) Inventor: Takeo FUNAKAWA, Chino (JP)

(73) Assignee: SEIKO EPSON CORPORATION, Tokyo (JP)

(21) Appl. No.: 13/856,600

(22) Filed: Apr. 4, 2013

(30) Foreign Application Priority Data
Apr. 10, 2012 (JP) 2012-089665
Apr. 10, 2012 (JP) 2012-089667

(51) Int. Cl. H01L 41/047; H01L 41/053

(52) U.S. Cl. CPC H01L 41/0472; H01L 41/0533
USPC 310/365

(57) ABSTRACT

A sensor element (a vibrator element) includes a base portion; a vibrating arm extended from the base portion; a drive unit that is provided in the vibrating arm and has a first electrode layer, a second electrode layer, and a piezoelectric body layer; a wiring having a portion that is drawn from the second electrode layer and is provided along a side surface of the piezoelectric body layer; and a terminal that is provided in the base portion and is electrically connected to the second electrode layer via the wiring.

### BACKGROUND

1. Technical Field

The present invention relates to a vibrator element, a vibration device and an electronic apparatus.

2. Related Art

For example, a sensor element configured to detect physical quantities such as angular velocity and acceleration is used for a vehicle body control in a vehicle, vehicle position detection of a car navigation system, a vibration control correction (a so-called blurring correction) of a digital camera, a video camera or the like. As such a sensor element, for example, a vibration gyro sensor (an angular velocity sensor) has been known (for example, see JP-A-2003-152232).

For example, the angular velocity sensor described in JP-A-2003-152232 includes a substrate of a tuning fork shape having two arm portions. A lower electrode layer, a piezoelectric layer and an upper electrode layer are stacked on each arm portion in this order. Furthermore, in the angular velocity sensor described in JP-A-2003-152232, a part of the upper electrode layer is divided into an excitation electrode portion and a detection electrode portion.

In the angular velocity sensor described in JP-A-2003-152232, by applying the voltage between the excitation electrode portion and the lower electrode layer, each arm portion is vibrated in directions approaching and separated from each other. Moreover, in that state, when receiving the angular velocity around an axis along the extension direction of each arm portion, each arm portion is bent in a direction perpendicular to the above-mentioned vibration direction by Coriolis force, and an electric charge due to an amount of bending is detected from the detection electrode unit. The angular velocity can be detected based on the detected electric charge.

However, in such an angular velocity sensor of the related art, when conducting with other components by a wire bonding, there has been a need to fix the bonding wire to the upper electrode layer on the piezoelectric layer. At that time, since it cannot be necessarily said that adhesion properties between the piezoelectric layer and the upper electrode layer is high, there has been a problem in that the upper electrode layer may be peeled off and a drop of reliability may be caused.

### SUMMARY

An advantage of some aspects of the invention is to provide a vibrator element and a vibration device capable of being made at a high yield and having high reliability, and an electronic apparatus including such a vibration device that has high reliability.

The invention can be implemented as the following forms or application examples.

### Application Example 1

This application example is directed to a vibrator element including a base portion; a vibrating arm extended from the base portion; a first piezoelectric body element that is provided in the vibrating arm, and has a first lower electrode layer, a first upper electrode layer provided on a side opposite to the vibrating arm with respect to the first lower electrode layer, and a first piezoelectric body layer provided between the first lower electrode layer and the first upper electrode layer; wiring having a portion that is drawn from the first upper electrode layer and is provided along the side surface of the first piezoelectric body layer; and a terminal that is provided in the base portion and is electrically connected to the first upper electrode layer via the wiring.

According to the vibrator element configured in this manner, it is possible to cause the electric current to flow through the first upper electrode layer using the terminal directly provided in the base portion, without going through the first piezoelectric body layer. Furthermore, since the terminal directly provided in the base portion without going through the first piezoelectric body layer has superior cohesion properties with the base portion, even when performing the wire bonding, the terminal can be prevented from peeling off, and has superior reliability.

Thus, the vibration device can be manufactured at a high yield, and the vibrator element having high reliability can be provided.

### Application Example 2

In the vibrator element according to the application example, it is preferable that the vibrator element further includes an insulator layer which is provided between the side surface of the first piezoelectric body layer and the first lower electrode layer and the wiring and is formed by a material that is different from the first piezoelectric body layer.

Thereby, it is possible to perform the bridge wiring to the first upper electrode layer on the first piezoelectric body layer, while preventing a short circuit between the wiring and the first lower electrode layer by the insulator layer. Furthermore, by suitably selecting the constitution material of the insulator layer, it is possible to prevent the adverse effects to the characteristics of the vibrator element due to the insulator layer.

### Application Example 3

In the vibrator element according to the application example, it is preferable that, when a dielectric constant of the first piezoelectric body layer is assumed to be ∈p and a dielectric constant of the insulator layer is assumed to be ∈i, a relationship of ∈p>∈i is satisfied.

Thereby, it is possible to perform the bridge wiring to the first upper electrode layer on the first piezoelectric body layer, while preventing a short circuit between the wiring and the first lower electrode layer by the insulator layer. Particularly, since the dielectric constant of the insulator layer is smaller than that of the first piezoelectric body layer, a parasitic capacitance between the wiring and the first lower electrode layer can be reduced. For that reason, it is possible to prevent the adverse effects to the vibrator element due to the wiring.

### Application Example 4

In the vibrator element according to the application example, it is preferable that the insulator layer has a portion provided on the first upper electrode layer side with respect to the first piezoelectric body layer, and a part of the first upper electrode layer is interposed between the portion and the first piezoelectric body layer.

Thereby, an electrode area of the first upper electrode layer can be increased. For that reason, the superior electric field efficiency of the first piezoelectric body element can be obtained.

### Application Example 5

In the vibrator element according to the application example, it is preferable that the insulator layer has a portion provided on the first upper electrode layer side with respect to the first piezoelectric body layer, and the first upper electrode layer is not present between the portion and the first piezoelectric body layer.

Thereby, when manufacturing the piezoelectric piece, after forming the insulator layer, the first upper electrode layer and the wiring can be formed together. For that reason, the manufacturing process of the vibrator element can be simplified.

### Application Example 6

In the vibrator element according to the application example, it is preferable that a thickness of the insulator layer is thicker than that of the first lower electrode layer.

Thereby, it is possible to simply and reliably cover the side surface of the first lower electrode layer by the insulator layer.

### Application Example 7

In the vibrator element according to the application example, it is preferable that the first piezoelectric body layer is provided so that a portion between the wiring and the first lower electrode layer covers the side surface of the first lower electrode layer.

Thereby, it is possible to prevent a short circuit between the wiring and the first lower electrode layer by the first piezoelectric body layer. For that reason, there is no need to separately form an insulator layer for preventing a short circuit, and the manufacturing cost can be simplified.

### Application Example 8

In the vibrator element according to the application example, it is preferable that the side surface of the first piezoelectric body layer is inclined with respect to a main surface of the first lower electrode layer.

Thereby, it is possible to prevent a disconnection of the wiring due to a step of the first piezoelectric body layer, and the damage of the insulator layer. Furthermore, it is possible to increase the film forming characteristics when forming the wiring and the insulator layer.

### Application Example 9

In the vibrator element according to the application example, it is preferable that the first upper electrode layer and the wiring are formed of the same material.

Thereby, when manufacturing the vibrator element, the first upper electrode layer and the wiring can be formed together. For that reason, the manufacturing process of the vibrator element can be simplified.

### Application Example 10

In the vibrator element according to the application example, it is preferable that the first upper electrode layer and the wiring is integrally formed.

Thereby, when manufacturing the vibrator element, the first upper electrode layer and the wiring can be formed together. For that reason, the manufacturing process of the vibrator element can be simplified.

### Application Example 11

In the vibrator element according to the application example, it is preferable that the vibrator element further includes a second piezoelectric body element that is provided in the vibrating arm, and has a second lower electrode layer, a second upper electrode layer provided on a side opposite to the vibrating arm with respect to the second lower electrode layer, and a second piezoelectric body layer provided between the second lower electrode layer and the second upper electrode layer, wherein the wiring is electrically connected to the second lower electrode layer.

According to the first piezoelectric body element and the second piezoelectric body element (a pair of drive units), since the parasitic capacitance between the wiring and the first lower electrode layer can be reduced, a drop of the drive force due to the wiring can be prevented.

### Application Example 12

This application example is directed to a vibration device including the vibrator element of the application example.

Thereby, it is possible to provide the vibration device having the superior reliability.

### Application Example 13

This application example is directed to an electronic apparatus including the vibrator element of the application example.

Thereby, it is possible to provide the electronic apparatus having the superior reliability.

### BRIEF DESCRIPTION OF THE DRAWINGS

The invention will be described with reference to the accompanying drawings, wherein like numbers reference like elements.

FIG. 1 is a schematic cross-sectional view that shows a schematic configuration of a sensor device (a vibration device) related to a first embodiment of the invention.

FIG. 2 is a plan view of the sensor device shown in FIG. 1.

FIG. 3 is a plan view that shows a sensor element (a vibrator element) included in the sensor device shown in FIG. 1.

FIG. 4 is a cross-sectional view of a line A-A in FIG. 3.

FIG. 5A is a cross-section view of a line B-B in FIG. 3, and FIG. 5B is a cross-sectional view of a line C-C in FIG. 3.

FIGS. 6A to 6C are diagrams for illustrating an example of a manufacturing method of the sensor element shown in FIG. 3.

FIGS. 7A to 7C are diagrams for illustrating an example of a manufacturing method of the sensor element shown in FIG. 3.

FIGS. 8A and 8B are diagrams for illustrating a sensor element (a vibrator element) related to a second embodiment of the invention.

FIGS. 9A and 9B are diagrams for illustrating a sensor element (a vibrator element) related to a third embodiment of the invention.

FIGS. 10A and 10B are diagrams for illustrating a sensor element (a vibrator element) related to a fourth embodiment of the invention.

FIGS. 11A and 11B are diagrams for illustrating a sensor element (a vibrator element) related to a fifth embodiment of the invention.

FIG. 12 is a diagram for illustrating a sensor element (a vibrator element) related to a sixth embodiment of the invention.

FIG. 13 is a cross-sectional view of a line D-D in FIG. 12.

FIG. 14 is a diagram for illustrating an operation of the sensor element shown in FIG. 12.

FIG. 15 is a diagram for illustrating a sensor element related to a seventh embodiment of the invention.

FIG. 16 is a diagram for illustrating a sensor element related to an eighth embodiment of the invention.

FIG. 17 is a perspective view that shows a configuration of a mobile type (or a notebook type) personal computer to which an electronic apparatus of the invention is applied.

FIG. 18 is a perspective view that shows a configuration of a mobile phone (also including PHS) to which the electronic apparatus of the invention is applied.

FIG. 19 is a perspective view that shows a configuration of a digital still camera to which the electronic apparatus of the invention is applied.

### DESCRIPTION OF EXEMPLARY EMBODIMENTS

Hereinafter, a vibrator element, a method of manufacturing the vibrator element, a vibration device and an electronic apparatus of the invention will be described in detail based on embodiments shown in the attached drawings. In addition, although an example of a case where the invention is applied to the vibrator element of the sensor will be described below, the invention is not limited thereto but can also be applied to, for example, a vibrator element of an oscillator.

### First Embodiment

First, a first embodiment of the invention will be described.

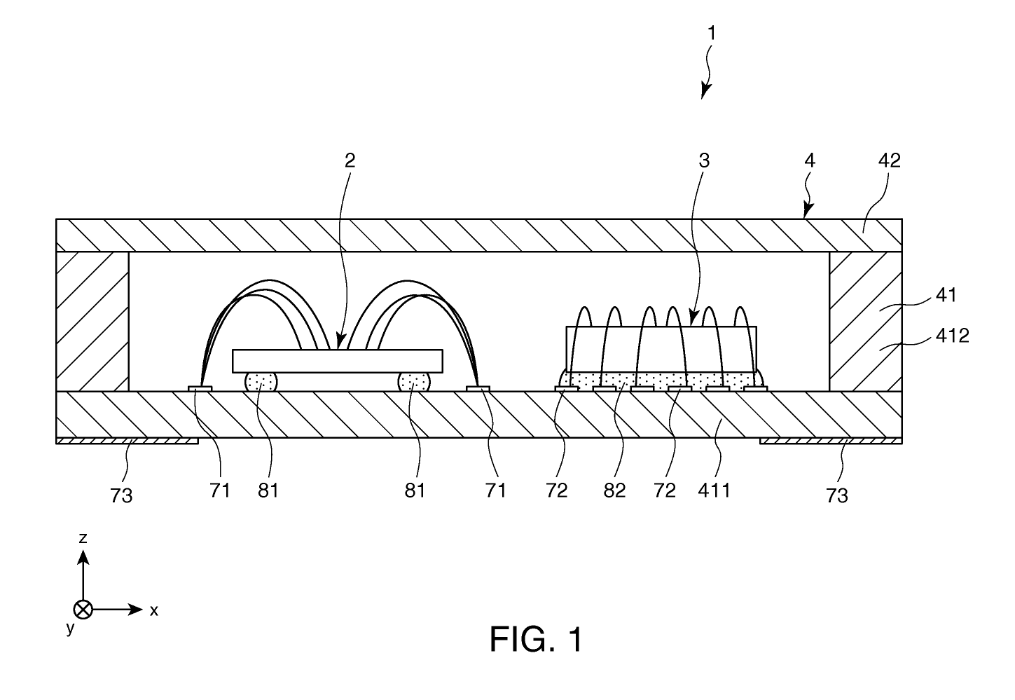

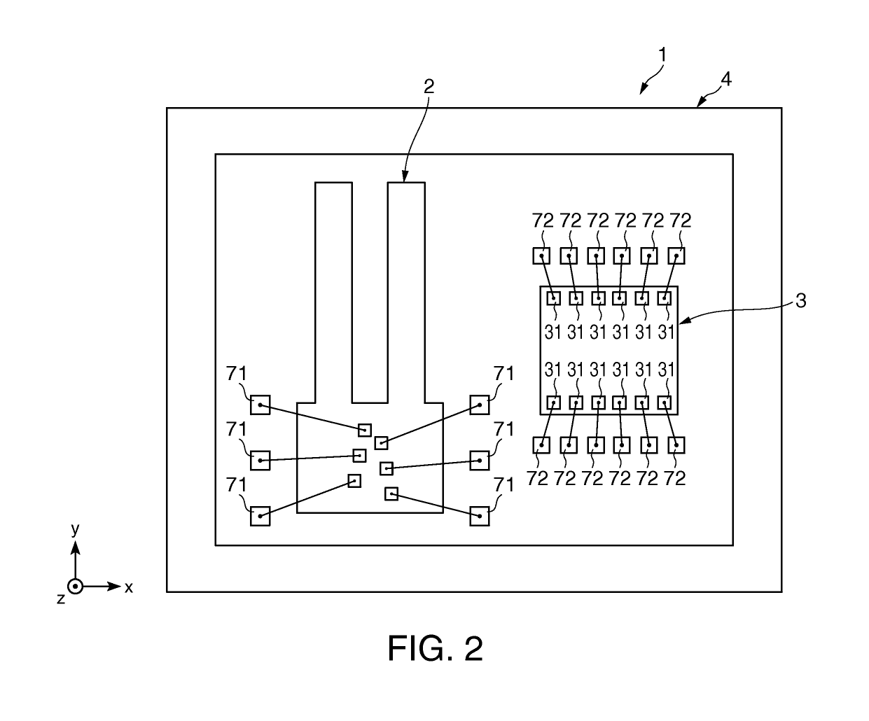

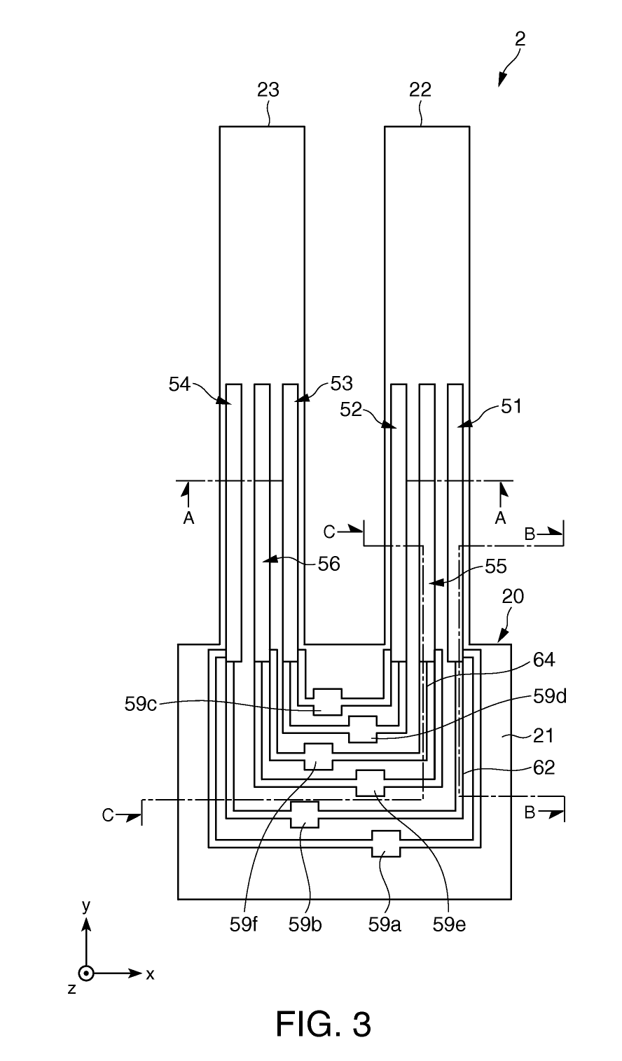

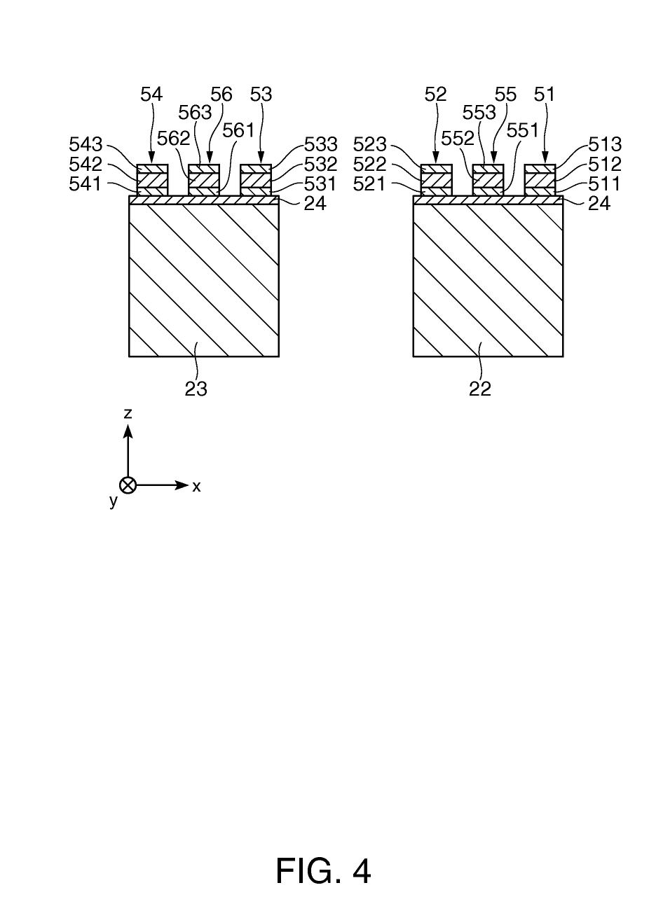

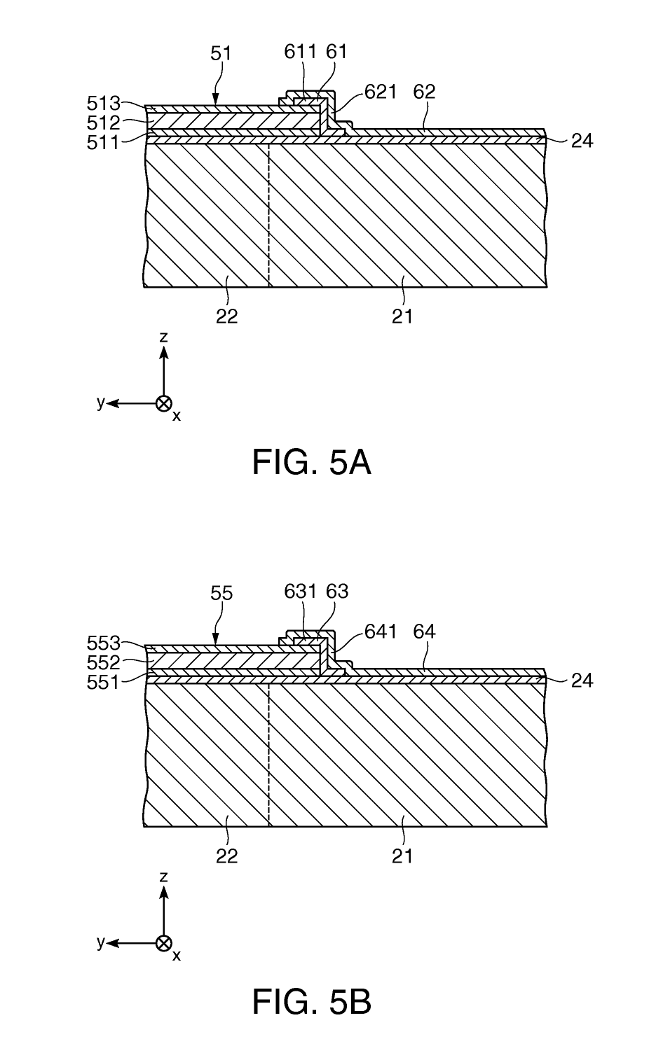

FIG. 1 is a schematic cross-sectional view that shows a schematic configuration of a sensor device (a vibration device) related to a first embodiment of the invention. FIG. 2 is a plan view of the sensor device shown in FIG. 1. FIG. 3 is a plan view that shows a sensor element (a vibrator element) included in the sensor device shown in FIG. 1. FIG. 4 is a cross-sectional view taken along line A-A in FIG. 3. FIG. 5A is a cross-sectional view taken along line B-B in FIG. 3, and FIG. 5B is a cross-sectional view taken along line C-C in FIG. 3.

In addition, for convenience of description, in FIGS. 1 to 5B, as three axes perpendicular to each other, an x axis, a y axis and a z axis are shown, and a leading end side of a shown arrow is referred to as a “+ side”, and a proximal end side thereof is referred to as a “− side”. Furthermore, a direction parallel to the x axis is referred to as an “x axis direction”, a direction parallel to the y axis is referred to as a “y axis direction”, and a direction parallel to the z axis is referred to as a “z axis direction”. Furthermore, a+z side (the upside in FIG. 1) is also referred to as an “up”, and a−z side (the downside in FIG. 1) is also referred to as a “down”.

### Sensor Device

The sensor device 1 shown in FIGS. 1 and 2 is a gyro sensor that detects an angular velocity.

For example, the sensor device 1 can be used for a blurring correction of an imaging device, and posture detection and a posture control of a vehicle or the like in a moving element navigation system using a GPS (Global Positioning System) satellite signal or the like.

As shown in FIGS. 1 and 2, the sensor device 1 has a sensor element 2, an IC chip 3, and a package 4 that stores the sensor element 2 and the IC chip 3. In addition, the IC chip 3 may be provided outside the package 4 and may be excluded depending on a device into which the sensor device 1 is incorporated.

Hereinafter, each portion constituting the sensor device 1 will be sequentially described.

### Sensor Element

The sensor element 2 is a gyro sensor element (a vibrator element) that detects the angular velocity around one axis.

As shown in FIG. 3, the sensor element 2 has a vibrating body 20, drive units 51 to 54 provided on the vibrating body 20, detection units 55 and 56, and terminals 59a to 59f.

### Vibrating Body

The vibrating body 20 includes a base portion 21 and two (a pair of) vibrating arms 22 and 23.

The two vibrating arms 22 and 23 are each extended and provided from the base portion 21 so as to be parallel to each other. More specifically, the two vibrating arms 22 and 23 each extend in the y axis direction (+y side) from the base portion 21, and are provided side by side in the x axis direction.

The vibrating arms 22 and 23 each form a rectangular shape, end portions (proximal end portions) of the base portion 21 side are fixed ends, and end portions (leading end portions) of a side opposite to the base portion 21 are free ends.

Furthermore, a cross-sectional surface of each of the vibrating arms 22 and 23 form a quadrangular form (see FIG. 4). In addition, a cross-sectional surface shape of each of the vibrating arms 22 and 23 is not limited to the quadrangular shape, and may form an H shape, for example, by forming grooves along the y axis direction on an upper surface and a lower surface of each of the vibrating arms 22 and 23.

In addition, as needed, in each of the leading end portions of the vibrating arms 22 and 23, a mass portion (a hammer head) having a cross-sectional area (a width) greater than that of the proximal end portion may be provided. In this case, the vibrating body 20 may be further reduced in size and a resonance frequency of each of the vibrating arms 22 and 23 may be further reduced.

Furthermore, in the leading end portion of each of the vibrating arms 22 and 23, an adjustment film (weight) for adjusting the resonance frequency of the vibrating arms 22 and 23 may be provided.

As a constitution material of the vibrating body 20, if desired vibration characteristics can be exhibited, various piezoelectric body materials and various non-piezoelectric body materials can be used, without being particularly limited.

For example, as the piezoelectric body material forming the vibrating body 20, crystal, lithium tantalite, lithium niobate, lithium borate, barium titanate or the like are adopted. Particularly, as the piezoelectric body material forming the vibrating body 20, crystal (an X cut plate, an AT cut plate, a Z cut plate or the like) is preferable. When forming the vibrating body 20 by crystal, the superior vibration characteristics (particularly, frequency temperature characteristics) of the vibrating body 20 can be obtained. Furthermore, the vibrating body 20 can be formed at high accuracy in dimension by etching.

Furthermore, as the non-piezoelectric body material forming the vibrating body 20, for example, silicon, quartz or the like can be adopted. Particularly, as the non-piezoelectric body material forming the vibrating body 20, silicon is preferable. When forming the vibrating body 20 by silicon, it is possible to relatively cheaply realize the vibrating body 20 having the superior vibration characteristics. Furthermore, it is possible to form the vibrating body 20 at high size accuracy by etching using a known fine processing technology.

The vibrating arm 22 of the vibrating body 20 is provided with a pair of drive units 51 and 52 and a detection unit 55, and the vibrating arm 23 is similarly provided with a pair of drive units 53 and 54 and a detection unit 56.

In the present embodiment, as shown in FIG. 4, on the upper surface of the vibrating body 20, an insulator layer 24 is provided. Thereby, it is possible to prevent a short circuit between the respective portions of the drive units 51 to 54 and the detection units 55 and 56.

For example, the insulator layer 24 is formed of SiO₂ (silicon oxide), Al₂O₃ (aluminum oxide), SiN (silicon nitride) or the like. Furthermore, as the forming method of the insulator layer 24, known film forming methods can be used without being particularly limited. For example, when the vibrating body 20 is formed of silicon, by performing the thermal oxidation of the upper surface of the vibrating body 20, the insulator layer 24 formed of SiO₂ can be formed.

Hereinafter, the drive units 51 to 54 and the detection units 55 and 56 will be sequentially described in detail.

### Drive Unit

First, the drive units 51 to 54 will be described.

The pair of drive units 51 and 52 is a piezoelectric body element (a first piezoelectric body element) that bends and vibrates the vibrating arm 22 in the x axis direction, respectively. Similarly, the pair of drive units 53 and 54 is a piezoelectric body element (a first piezoelectric body element) that bends and vibrates the vibrating arm 23 in the x axis direction, respectively.

The pair of drive units 51 and 52 is configured so that the drive unit 51 is provided on one side (the right side in FIG. 3) in the width direction (the x axis direction) of the vibrating arm 22, and the drive unit 52 is provided on the other side (the left side in FIG. 3) thereof.

Similarly, the pair of drive units 53 and 54 is configured so that the drive unit 53 is provided on one side (the right side in FIG. 3) in the width direction (the x axis direction) of the vibrating arm 23, and the drive unit 54 is provided on the other side (the left side in FIG. 3) thereof.

In the present embodiment, the drive units 51 and 52 are mainly provided in the portion of the proximal end side of the vibrating arm 22. Similarly, the drive units 53 and 54 are mainly provided in the portion of the proximal end side of the vibrating arm 23.

Moreover, the drive units 51 to 54 are each constituted so as to extend and contract in the y axis direction by the electric conduction.

More specifically, as shown in FIG. 4, the drive unit 51 has a first electrode layer 511 (a first lower electrode layer), a second electrode layer 513 (a first upper electrode layer) provided on aside opposite to the vibrating arm 22 with respect to the first electrode layer 511, and a piezoelectric body layer 512 (a first piezoelectric body layer) provided between the first electrode layer 511 and the second electrode layer 513. In other words, the drive unit 51 is configured so that the first electrode layer 511, the piezoelectric body layer (the piezoelectric thin film) 512, and the second electrode layer 513 are stacked on the vibrating arm 22 in this order.

Similarly, the drive unit 52 is configured so that a first electrode layer 521, a piezoelectric body layer (a piezoelectric thin film) 522, and a second electrode layer 523 are stacked on the vibrating arm 22 in this order. Furthermore, the drive unit 53 is configured so that a first electrode layer 531, a piezoelectric body layer (a piezoelectric thin film) 532, and a second electrode layer 533 are stacked on the vibrating arm 23 in this order. Furthermore, the drive unit 54 is configured so that a first electrode layer 541, a piezoelectric body layer (a piezoelectric thin film) 542, and a second electrode layer 543 are stacked on the vibrating arm 23 in this order.

By the use of the drive units 51 to 54, even when the vibrating arms 22 and 23 themselves do not have piezoelectric characteristics or the vibrating arms 22 and 23 themselves have piezoelectric characteristics, even in a case where the directions of a polarization axis and a crystal axis are not suitable for the bending vibration in the x axis direction, it is possible to relatively simply and effectively bend and vibrate (drive and vibrate) each of the vibrating arms 22 and 23 in the x axis direction. Furthermore, since the presence or absence of the piezoelectric characteristics of the vibrating arms 22 and 23 and the directions of the polarization axis and the crystal axis does not matter, the width of the selection of the constitution material of each of the vibrating arms 22 and 23 is widened. For that reason, it is possible to relatively simply realize the vibrating body 20 having desired vibration characteristics.

Hereinafter, each layer forming the drive unit 51 will be sequentially described. In addition, since the drive units 52 to 54 are the same as the drive unit 51, the descriptions thereof will be omitted.

For example, the first electrode layer 511 can be formed of metallic materials such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn) and zirconium (Zr), and transparent electrode materials such as ITO and ZnO.

Among them, as the constitution material of the first electrode layer 511, it is preferable to use the metal (gold and gold alloy) mainly formed of gold or platinum, and it is more preferable to use metal (particularly, gold) mainly formed of gold.

Since Au has superior conductivity (small electrical resistance) and has superior tolerance to the oxidation, Au is preferable as the electrode material. Furthermore, Au can be easily pattered by etching compared to Pt. In addition, by forming the first electrode layer 511 by gold or gold alloy, the orientation of the piezoelectric body layer 512 can be increased.

Furthermore, although not particularly limited, an average thickness of the first electrode layer 511 is preferably, for example, substantially 1 to 300 nm, and more preferably, 10 to 200 nm. Thereby, the superior conductivity of the first electrode layer 511 as mentioned above can be obtained, while preventing the first electrode layer 511 from adversely affecting the drive characteristics of the drive unit 51 and the vibration characteristics of the vibrating arm 22.

In addition, a ground layer having a function of preventing the first electrode layer 511 from falling off from the vibrating arm 22 may be provided between the first electrode layer 511 and the vibrating arm 22.

Such a ground layer is formed of, for example, Ti, Cr or the like.

The piezoelectric body layer 512 is provided on the first electrode layer 511.

As the constitution material (the piezoelectric body layer) of the piezoelectric body layer 512, for example, zinc oxide (ZnO), aluminum nitride (AlN), lithium tantalite (LiTaO₃), lithium niobate (LiNbO₃), potassium niobate (KNbO₃), lithium tetraborate (Li₂B₄O₇), barium titanate (BaTiO₃), PZT (lead zirconate titanate) or the like are adopted.

Among them, as the constitution material of the piezoelectric body layer 512, it is preferable to use PZT. The PZT (lead zirconate titanate) has superior c axis orientation. For that reason, by forming the piezoelectric body layer 512 by the PZT as a main material, a CI value of the sensor element 2 can be reduced. Furthermore, such a material can be formed by a reactive sputtering method.

Furthermore, the average thickness of the piezoelectric body layer 512 is preferably 50 to 3000 nm, and more preferably, 200 to 2000 nm. Thereby, the superior drive characteristics of the drive unit 51 can be obtained, while preventing the piezoelectric body layer 512 from adversely affecting the vibration characteristics of the vibrating arm 22.

On the piezoelectric body layer 512 (on a surface of the piezoelectric body layer 512 of a side opposite to the vibrating arm 22), the second electrode layer 513 is provided.

For example, the second electrode layer 513 can be formed by metallic materials such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn) and zirconium (Zr), and transparent electrode materials such as ITO and ZnO.

Furthermore, although the average thickness of the second electrode layer 513 is not particularly limited, the average thickness is preferably substantially 1 to 300 nm, and more preferably, 10 to 200 nm. Thereby, the superior conduction characteristics of the second electrode layer 513 can be obtained, while preventing the second electrode layer 513 from adversely affecting the drive characteristics of the drive unit 51 and the vibration characteristics of the vibrating arm 22.

In addition, between the piezoelectric body layer 512 and the second electrode layer 513, an insulator layer (an insulating protective layer) may be provided which protects the piezoelectric body layer 512 and has a function of preventing a short circuit between the first electrode layer 511 and the second electrode layer 513.

For example, the insulator layer is formed of, for example, SiO₂ (silicon oxide), Al₂O₃ (aluminum oxide), SiN (silicon nitride) or the like.

Furthermore, between the piezoelectric body layer 512 and the second electrode layer 513, a ground layer having a function of preventing the second electrode layer 513 from peeling off from the piezoelectric body layer 512 (when providing the above-mentioned insulator layer, the insulator layer) may be provided.

Such a ground layer may be formed of, for example, Ti, Cr or the like.

In the drive unit 51 configured in this manner, when the voltage is applied between the first electrode layer 511 and the second electrode layer 513, an electric field in the z axis direction is generated in the piezoelectric body layer 512, and the piezoelectric body layer 512 extends or contracts in the y axis direction. Similarly, in the drive unit 52, when the voltage is applied between the first electrode layer 521 and the second electrode layer 523, an electric field in the z axis direction is generated in the piezoelectric body layer 522, and the piezoelectric body layer 522 extends or contracts in the y axis direction.

At this time, when extending one drive unit of the drive units 51 and 52 in the y axis direction, by contracting the other thereof in the y axis direction, the vibrating arm 22 can be bent and vibrated in the x axis direction.

Similarly, it is possible to bend and vibrate the vibrating arm 23 in the x axis direction by the drive units 53 and 54.

In the present embodiment, the first electrode layer 511 of the drive unit 51 and the first electrode layer 541 of the drive unit 54 are each electrically connected to the terminal 59a provided in the base portion 21 shown in FIG. 3. Furthermore, the second electrode layer 513 of the drive unit 51 and the second electrode layer 543 of the drive unit 54 are each electrically connected to the terminal 59b provided in the base portion 21 shown in FIG. 3. Moreover, the first electrode layer 521 of the drive unit 52 and the first electrode layer 531 of the drive unit 53 are each electrically connected to the terminal 59c provided in the base portion 21 shown in FIG. 3. Additionally, the second electrode layer 523 of the drive unit 52 and the second electrode layer 533 of the drive unit 53 are each electrically connected to the terminal 59d provided in the base portion 21 shown in FIG. 3.

Thus, by applying the voltage between the terminals 59a and 59d and the terminals 59b and 59c, while making the electric potential of the terminal 59a equal to that of the terminal 59d, and making the electric potential of the terminal 59b equal to that of the terminal 59c, the vibrating arms 22 and 23 can be bent and vibrated in the x axis direction so as to approach and be separated from each other.

Herein, the wiring through which the drive unit 51 and the terminals 59a and 59b are electrically connected to each other will be described. In addition, since the wiring through which the drive unit 54 is electrically connected to the terminals 59a and 59b, and the wiring, through which the drive units 52 and 53 are electrically connected to the terminals 59c and 59d, are the same as the wiring through which the drive unit 51 is electrically connected to the terminals 59a and 59b, the description thereof will be omitted.

As shown in FIG. 5A, a wiring 62 electrically connected to the terminal 59b is drawn to the second electrode layer 513 of the drive unit 51. Furthermore, although not shown, a wiring electrically connected to the terminal 59a is drawn to the first electrode layer 511 of the drive unit 51.

The wiring 62 has a portion 621 that is provided along the side surface of the piezoelectric body layer 512. Thereby, it is possible to perform the bridge wiring to the second electrode layer 513 on the piezoelectric body layer 512.

Furthermore, between the side surfaces of the piezoelectric body layer 512 and the first electrode layer 511 and the wiring 62, an insulator layer 61 is provided. Thereby, a short circuit between the wiring 62 and the first electrode layer 511 can be prevented.

Particularly, when assuming a dielectric constant of the piezoelectric body layer 512 to ∈p, and a dielectric constant of the insulator layer 61 to ∈i, a relationship of ∈p>∈i is satisfied.

Thereby, since the dielectric constant of the insulator layer 61 is smaller than that of the piezoelectric body layer 512, a parasitic capacitance between the wiring 62 and the first electrode layer 511 can be reduced. For that reason, it is possible to prevent the adverse effects to the characteristics of the sensor element 2 due to the wiring 62. Specifically, the drop of the drive force of the drive unit 51 due to the parasitic capacitance can be prevented.

As the constitution material of the insulator layer 61, if a material has insulating properties and satisfies the relationship of the dielectric constant as mentioned above, an insulating inorganic compound, and a resin material can be adopted, without being particularly limited. For example, when the piezoelectric body layer 512 is formed of PZT, TiO₂, HfO₂, SiO₂, Al₂O₃, SiN, SiC or the like can be used, and when the piezoelectric body layer 512 is formed of ZnO or AlN, SiO₂, Al₂O₃ or the like can be used.

Furthermore, a difference between the dielectric constant ∈p of the piezoelectric body layer 512 and the dielectric constant E1 of the insulator layer 61 is preferably 1 [F/m] or more, and more preferably, 2 [F/m] or more.

In this manner, since the terminal 59b provided in the base portion 21 is electrically connected to the second electrode layer 513 via the wiring 62, it is possible to cause electric current to flow through the second electrode layer 513 using the terminal 59b directly provided in the base portion 21, without going through the piezoelectric body layer 512. Furthermore, since the terminal 59b directly provided in the base portion 21 without going through the piezoelectric body layer 512 has superior adhesion properties with the base portion 21, the peeling-off thereof can be prevented even when performing the wire bonding, and superior reliability is obtained.

Furthermore, the insulator layer 61 has a portion 611 that extends from the side surface of the second electrode layer 513 and is provided on the second electrode layer 513 side with respect to the piezoelectric body layer 512. Moreover, between the portion 611 and the piezoelectric body layer 512, a part of the second electrode layer 513 is interposed. Thereby, an electrode area of the second electrode layer 513 can be increased. For that reason, the superior electric field efficiency of the drive unit 51 can be obtained. As a result, the drive force of the drive unit 51 can be increased.

Furthermore, the thickness of the insulator layer 61 is preferably thicker than that of the first electrode layer 511. Thereby, it is possible to simply and reliably cover the side surface of the first electrode layer 511 by the insulator layer 61.

### Detection Unit

Next, the detection units 55 and 56 will be described.

The detection unit 55 is a piezoelectric body element (a first piezoelectric body element) that detects the bending vibration (a so-called out-of-plane vibration) of the vibrating arm 22 in the z axis direction. Similarly, the detection unit 56 is a piezoelectric body element (a first piezoelectric body element) that detects the bending vibration of the vibrating arm 23 in the z axis direction.

The detection unit 55 is provided in a central portion of the vibrating arm 22 in the width direction (the x axis direction). Similarly, the detection unit 56 is provided in a central portion of the vibrating arm 23 in the width direction (the x axis direction).

In the present embodiment, the detection unit 55 is mainly provided in the portion of the proximal end side of the vibrating arm 22. Similarly, the detection unit 56 is mainly provided in the portion of the proximal end side of the vibrating arm 23.

Furthermore, the detection unit 55 is provided between the above-mentioned pair of drive units 51 and 52, and similarly, the detection unit 56 is provided between the above-mentioned pair of drive units 53 and 54.

Moreover, the detection units 55 and 56 are configured to output the electric change by extending and contracting in the y axis direction.

Specifically, as shown in FIG. 4, the detection unit 55 has a first electrode layer 551 (a first lower electrode layer), a second electrode layer 553 (a first upper electrode layer) provided on aside opposite to the vibrating arm. 22 with respect to the first electrode layer 551, and a piezoelectric body layer 552 (a first piezoelectric body layer) provided between the first electrode layer 551 and the second electrode layer 553. In other words, the detection unit 55 is configured so that the first electrode layer 551, the piezoelectric body layer (a piezoelectric thin film) 552, and the second electrode layer 553 are stacked on the vibrating arm 22 in this order.

Similarly, the detection unit 56 is configured so that a first electrode layer 561, a piezoelectric body layer (a piezoelectric thin film) 562, and a second electrode layer 563 are stacked on the vibrating arm 23 in this order.

By the use of the detection units 55 and 56 described above, even when the vibrating arms 22 and 23 themselves have or do not have the piezoelectric properties, and even in a case where the directions of the polarization axis and the crystal axis are not suitable for the detection of the bending vibration in the z axis direction, it is possible to relatively simply and effectively detect the bending vibration of each of the vibrating arms 22 and 23 in the z axis direction. Furthermore, since the presence or absence of the vibrating arms 22 and 23 and the directions of the polarization axis and the crystal axis do not matter, the width of the selection of the constitution material of each of the vibrating arms 22 and 23 broadens. For that reason, it is possible to relatively simply realize the vibrating body 20 having desired vibration characteristics.

Furthermore, the first electrode layers 551 and 561 can be formed by the same material as the first electrode layer of the above-mentioned drive units 51 to 54.

Moreover, the first electrode layers 551 and 561 can be formed by the same thickness as the first electrode layer of the above-mentioned drive units 51 to 54.

Additionally, the first electrode layers 551 and 561 can be formed together by the same process as the first electrode layer of the above-mentioned drive units 51 to 54.

Furthermore, the piezoelectric body layers 552 and 562 can be formed by the same material as the piezoelectric body layers of the above-mentioned drive units 51 to 54.

Moreover, the piezoelectric body layers 552 and 562 can be formed by the same thickness as the piezoelectric body layers of the above-mentioned drive units 51 to 54.

Additionally, the piezoelectric body layers 552 and 562 can be formed together by the same process as the piezoelectric body layers of the above-mentioned drive units 51 to 54.

Furthermore, the second electrode layers 553 and 563 can be formed by the same material as the second electrode layer of the above-mentioned drive units 51 to 54.

Moreover, the second electrode layers 553 and 563 can be formed by the same thickness as the second electrode layer of the above-mentioned drive units 51 to 54.

Additionally, the second electrode layers 553 and 563 can be formed together by the same process as the second electrode layer of the above-mentioned drive units 51 to 54.

The detection unit 55 configured in this manner extends or contracts in the y axis direction and outputs the electric charge, when the vibrating arm 22 is bent in the z axis direction. Thereby, the detection unit 55 outputs the electric charge along with the bending vibration of the vibrating arm 22 in the z axis direction.

Similarly, the detection unit 56 outputs the electric charge along with the bending vibration of the vibrating arm 23 in the z axis direction.

In the present embodiment, the first electrode layer 551 of the detection unit 55 and the second electrode layer 563 of the detection unit 56 are electrically connected to the terminal 59f provided in the base portion 21 shown in FIG. 3. Furthermore, the second electrode layer 553 of the detection unit 55 and the first electrode layer 561 of the detection unit 56 are electrically connected to the terminal 59e provided in the base portion 21 shown in FIG. 3.

Thus, when the vibrating arms 22 and 23 are subjected to the bending vibration to the opposite sides in the z axis direction, an electric potential difference occurs between the terminal 59e and the terminal 59f along with the bending vibration.

Herein, the wiring through which the detection unit 55 is electrically connected to the terminals 59e and 59f will be described. In addition, since the wiring through which the detection unit 56 is electrically connected to the terminals 59e and 59f is the same as the wiring through which the detection unit 55 is electrically connected to the terminals 59e and 59f, the description thereof will be omitted.

As shown in FIG. 5B, a wiring 64 electrically connected to the terminal 59f is drawn to the second electrode layer 553 of the detection unit 55. Furthermore, although not shown, a wiring electrically connected to the terminal 59e is drawn to the first electrode layer 551 of the detection unit 55.

The wiring 64 has a portion 641 that is provided along the side surface of the piezoelectric body layer 552. Thereby, it is possible to perform the bridge wiring to the second electrode layer 553 on the piezoelectric body layer 552.

Furthermore, between the side surfaces of the piezoelectric body layer 552 and the first electrode layer 551 and the wiring 64, an insulator layer 63 is provided. Thereby, a short circuit between the wiring 64 and the first electrode layer 551 can be prevented.

Particularly, when assuming a dielectric constant of the piezoelectric body layer 552 to ∈p, and a dielectric constant of the insulator layer 63 to ∈i, a relationship of ∈p>∈i is satisfied.

Thereby, since the dielectric constant of the insulator layer 63 is smaller than that of the piezoelectric body layer 552, a parasitic capacitance between the wiring 64 and the first electrode layer 551 can be reduced. For that reason, it is possible to prevent the adverse effects to the characteristics of the sensor element 2 due to the wiring 64. Specifically, the drop of the detection sensitivity of the detection unit 55 due to the parasitic capacitance can be prevented.

As the constitution material of the insulator layer 63, if a material has insulating properties and satisfies the relationship of the dielectric constant as mentioned above, the same materials as the constitution materials of the above-mentioned insulator layer 61 can be adopted, without being particularly limited.

Furthermore, a difference between the dielectric constant ∈p of the piezoelectric body layer 552 and the dielectric constant ∈i of the insulator layer 63 is preferably 1 [F/m] or more, and more preferably, 2 [F/m] or more.

In this manner, since the terminal 59f provided in the base portion 21 is electrically connected to the second electrode layer 553 via the wiring 64, it is possible to cause electric current to flow through the second electrode layer 553 using the terminal 59f directly provided in the base portion 21, without going through the piezoelectric body layer 552. Furthermore, since the terminal 59f directly provided in the base portion 21 without going through the piezoelectric body layer 552 has superior adhesion properties with the base portion 21, the peeling-off thereof can be prevented even when performing the wire bonding, and superior reliability is obtained.

Furthermore, the insulator layer 63 has a portion 631 that extends from the side surface of the second electrode layer 553 and is provided on the second electrode layer 553 side with respect to the piezoelectric body layer 552. Moreover, between the portion 631 and the piezoelectric body layer 552, a part of the second electrode layer 553 is interposed. Thereby, an electrode area of the second electrode layer 553 can be increased. For that reason, the superior electric field efficiency of the detection unit 55 can be obtained. As a result, the detection sensitivity of the detection unit 55 can be increased.

Furthermore, the thickness of the insulator layer 63 is preferably thicker than that of the first electrode layer 551. Thereby, it is possible to simply and reliably cover the side surface of the first electrode layer 551 by the insulator layer 63.

In the sensor element 2 configured as mentioned above, by applying the voltage between the terminals 59a and 59d and the terminals 59b and 59c, the vibrating arms 22 and 23 are subjected to the bending vibration (the driving vibration) in the x axis direction so as to approach and be separated from each other.

In this manner, in the state of performing the driving vibration of the vibrating arms 22 and 23, when an angular velocity ω around the y axis is applied to the sensor element 2, the vibrating arms 22 and 23 are subjected to the bending vibration (the detecting vibration) to the opposite sides in the z axis direction by Coriolis force.

By detecting the electric charge generated in the detection units 55 and 56 due to the detecting vibration of the vibrating arms 22 and 23 via the terminals 59e and 59f, the angular velocity ω applied to the sensor element 2 can be obtained.

The sensor element 2 as mentioned above can be manufactured by the following manufacturing method.

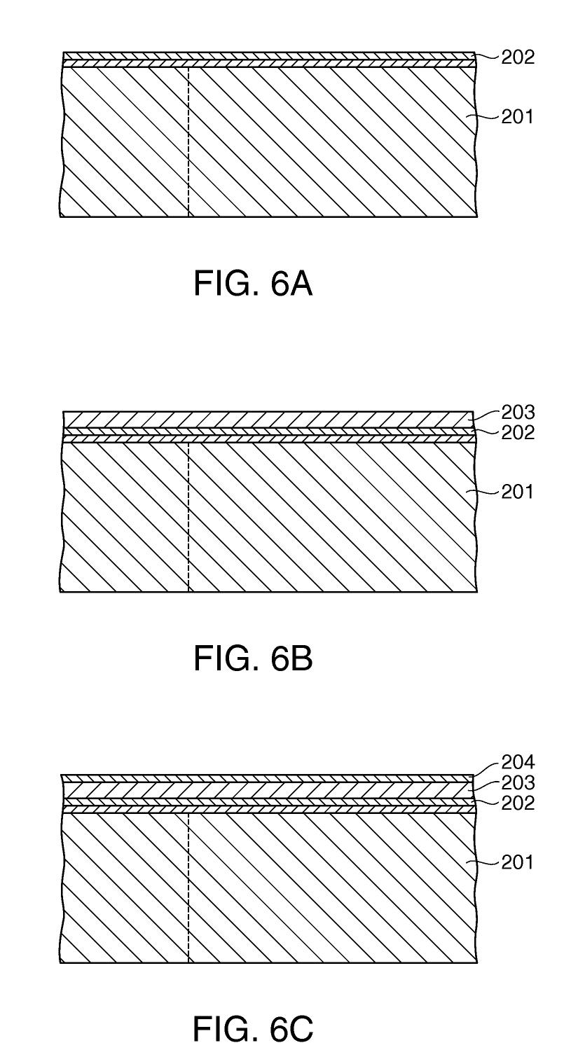

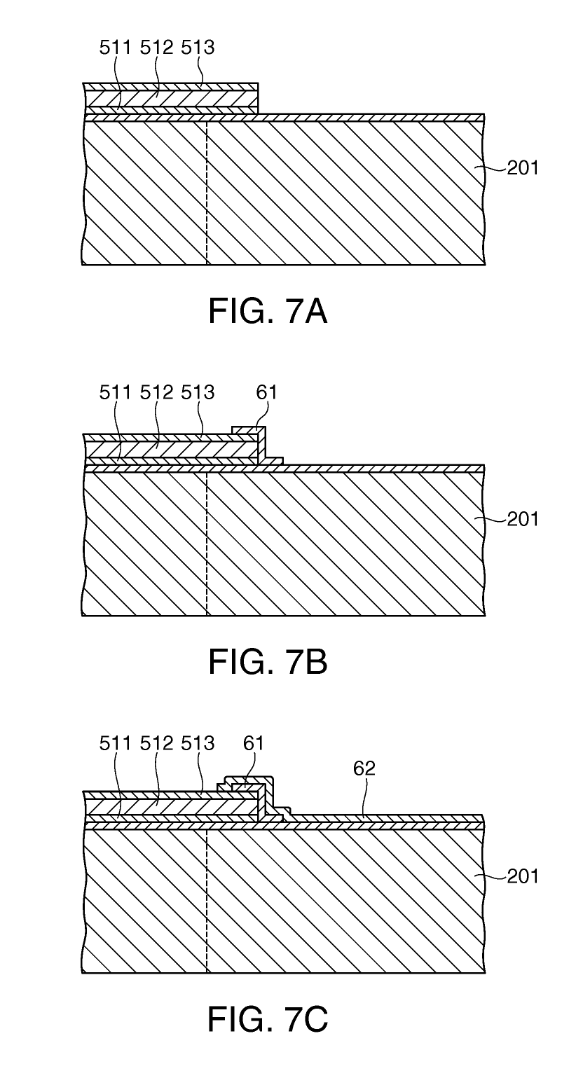

Hereinafter, as an example of the manufacturing method of the vibrator element of the embodiment of the invention, the manufacturing method of the sensor element 2 will be described based on FIGS. 6A to 7C.

FIGS. 6A to 7C are diagrams for illustrating the manufacturing method (an example of the manufacturing method of the vibrator element of the embodiment of the invention) of the sensor element shown in FIG. 3. In addition, hereinafter, for convenience of description, processes concerning the drive unit 51, the insulator layer 61 and the wiring 62 will be typically described.

The manufacturing method of the sensor element 2 has [A] a first process of forming the first electrode layer 511, the piezoelectric body layer 512, and the second electrode layer 513, [B] a second process of forming the insulator layer 61, and [C] a third process of forming the wiring 62.

Hereinafter, each process will be sequentially described in detail.

### A First Process

### A1

First, as shown in FIG. 6A, a conductor layer 202 is formed on a substrate 201.

The substrate 201 serves as the vibrating body 20 by being processed in a later process, and is formed by the same material as the above-mentioned constitution material of the vibrating body 20.

In addition, the substrate 201 performs the formation of an insulating layer for forming the insulator layer 24 as needed, before forming the conductor layer 202.

Furthermore, the conductor layer 202 serves as the first electrode layer 511 by being processed in a later process, and is formed by the same material as the above-mentioned constitution material of the first electrode layer 511.

Furthermore, as the forming method of the conductor layer 202, although not particularly limited, for example, dry type plating methods such as a vacuum deposition, sputtering (a low-temperature sputtering method), and an ion plating, wet type plating methods such as an electroplating, a non-electroplating, a spraying method, joining of a conductor foil and the like are adopted.

### A2

Next, as shown in FIG. 6B, a piezoelectric body layer 203 is formed on the conductor layer 202.

The piezoelectric body layer 203 serves as the piezoelectric body layer 512 by being processed in a later process, and is formed by the same material as the constitution material of the above-mentioned piezoelectric body layer 512.

As the forming method of the piezoelectric body layer 203, although not particularly limited, for example, a gas phase film forming method such as plasma CVD, a sol gel method, and a sputtering method are adopted.

### A3

Next, as shown in FIG. 6C, a conductor layer 204 is formed on the piezoelectric body layer 203.

The conductor layer 204 serves as the second electrode layer 513 by being processed in a later process, and is formed by the same material as the constitution material of the above-mentioned second electrode layer 513.

As the forming method of the conductor layer 204, the same method as the forming method of the above-mentioned conductor layer 202 can be used.

### A4

After sequentially stacking the conductor layer 202, the piezoelectric body layer 203 and the conductor layer 204, by etching the stacked body constituted by the conductor layer 202, the piezoelectric body layer 203 and the conductor layer 204, as shown in FIG. 7A, the first electrode layer 511, the piezoelectric body layer 512 and the second electrode layer 513 are formed.

As such etching, although not particularly limited, for example, RIE (reactive ion etching), dry etching using CF₄ or the like can be adopted.

Furthermore, at the time of etching, a mask formed by photolithography can be used.

### B Second Process

Next, as shown in FIG. 7B, the insulator layer 61 is formed.

As the forming method of the insulator layer 61, although not particularly limited, for example, a gas phase film forming method such as plasma CVD can be used. Furthermore, it is possible to use etching that uses the mask formed by the photolithography.

### C Third Process

Next, as shown in FIG. 7C, the wiring 62 is formed.

As the forming method of the wiring 62, although not particularly limited, for example, dry type plating methods such as a vacuum deposition, sputtering (a low-temperature sputtering), and an ion plating, wet type plating methods such as an electroplating, a non-electroplating, a spraying method, joining of a conductor foil and the like are adopted. Furthermore, it is possible to use etching that uses the mask formed by the photolithography.

After that, the vibrating body 20 is obtained by processing the substrate 201 using etching.

As the etching method, although not particularly limited, for example, it is possible to use one kind or two kinds or more of physical etching methods such as a plasma etching, a reactive ion etching, a beam etching and an optical assist etching, and chemical etching methods such as a wet etching in combination. Furthermore, at the time of etching as mentioned above, for example, the mask formed by the photolithography method can be used.

According to the manufacturing method of the sensor element 2 as mentioned above, it is possible to perform the bridge wiring to the second electrode layer 513, while preventing the adverse effects to the characteristics of the sensor element 2.

Particularly, since the second electrode layer 513 is formed before forming the insulator layer 61, the electrode area of the second electrode layer 513 can be increased. For that reason, the superior electric field efficiency of the provided drive unit 51 can be obtained.

### IC Chip

The IC chip 3 shown in FIGS. 1 and 2 is an electronic component that has a function of driving the above-mentioned sensor element 2 and a function of detecting the output (the sensor output) from the sensor element 2.

Although not shown, the IC chip 3 includes a drive circuit that drives the sensor element 2, and a detection circuit that detects the output from the sensor element 2.

Furthermore, a plurality of connection terminals 31 is provided in the IC chip 3.

### Package

As shown in FIGS. 1 and 2, the package 4 includes a base member 41 (a base) having a concave portion opened upward, and a lid member 42 (a lid) that is provided so as to cover the concave portion of the base member 41. Thereby, between the base member 41 and the lid member 42, an inner space is formed in which the sensor element 2 and the IC chip 3 are stored.

The base member 41 includes a tabular plate body 411 (a plate portion), and a frame body 412 (a frame portion) jointed to an outer circumferential portion of the upper surface of the plate body 411.

Such a base member 41 is formed of, for example, aluminum oxide sintered body, crystal, glass or the like.

As shown in FIG. 1, on the upper surface (a surface covered by the lid member 42) of the base member 41, for example, the base portion 21 of the above-mentioned sensor element 2 is joined by a joining member 81 such as an adhesive including epoxy resin, acrylic resin or the like. Thereby, the sensor element 2 is supported and fixed with respect to the base member 41.

Furthermore, on the upper surface of the base member 41, for example, the above-mentioned IC chip 3 is joined by a joining member 82 such as an adhesive including an epoxy resin, an acrylic resin or the like. Thereby, the IC chip 3 is supported and fixed with respect to the base member 41.

In addition, as shown in FIGS. 1 and 2, on the upper surface of the base member 41, a plurality of internal terminals 71 and a plurality of internal terminals 72 are provided.

For example, the terminals 59a to 59f of the above-mentioned sensor element 2 are electrically connected to the plurality of internal terminals 71, via the wiring constituted by the bonding wire.

The plurality of internal terminals 71 is electrically connected to the plurality of internal terminals 72 via a wiring (not shown).

Furthermore, for example, the plurality of connection terminals 31 of the above-mentioned IC chip 3 is electrically connected to the plurality of internal terminals 72 via a wiring constituted by the bonding wire.

Meanwhile, as shown in FIG. 1, on the lower surface (a bottom surface of the package 4) of the base member 41, a plurality of external terminals 73 is provided which is used when being instrumented on an apparatus (an external apparatus) to which the sensor device 1 is incorporated.

The plurality of external terminals 73 is electrically connected to the above-mentioned internal terminal 72 via an internal wiring (not shown). Thereby, the IC chip 3 and the plurality of external terminals 73 are electrically connected to each other.

Each of the internal terminals 71 and 72 and each external terminal 73 are each formed of, for example, a metallic coating in which coatings such as nickel (Ni) and gold (Au) are stacked on an metallized layer such as tungsten (W), using the plating or the like.

The lid member 42 is hermetically joined to the base member 41. Thereby, the inside of the package 4 is air tightly sealed.

For example, the lid member 42 is formed of the same material as the base member 41, or a metal such as kovar, 42 alloy and stainless steel.

As a method of joining the base member 41 and the lid member 42, for example, a joining method using an adhesive formed of a brazing filler metal, a hardening resin or the like, a welding method such as a seam welding and a laser welding or the like can be used.

By performing the joining under a reduced pressure or an inert gas atmosphere, the inside of the package 4 can be kept in a reduced pressure state or an inert gas sealing state.

According to the sensor element 2 provided in the sensor device 1 related to the first embodiment as mentioned above, it is possible to perform the bridge wiring to the upper electrode layer on the piezoelectric body layer, while preventing the adverse effects to the characteristics of the sensor element 2.

Furthermore, according to the sensor device 1 including the sensor element 2 as mentioned above, superior reliability is obtained.

### Second Embodiment

Next, a second embodiment of the invention will be described.

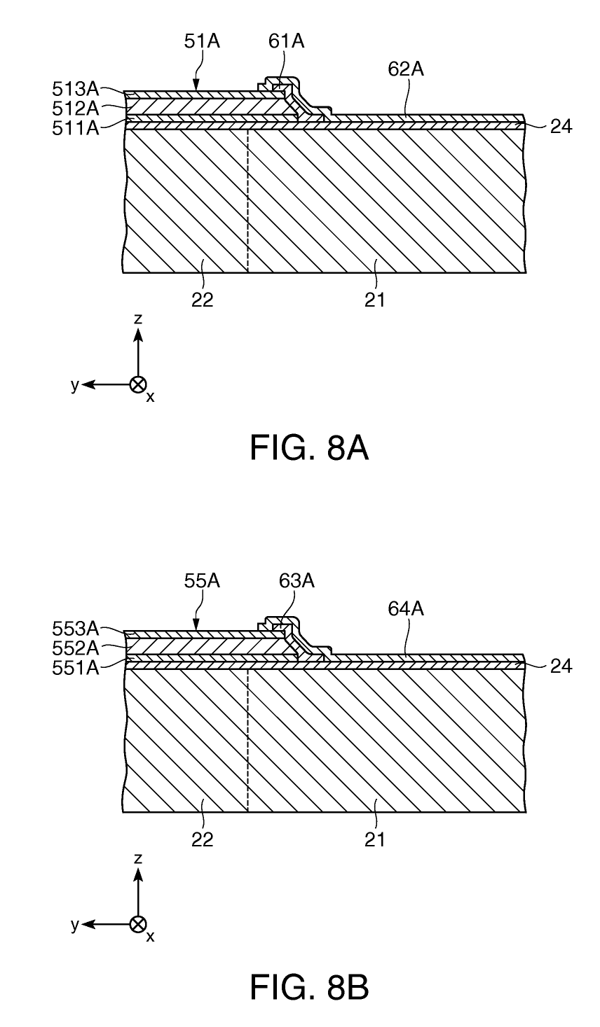

FIGS. 8A and 8B are diagrams for illustrating a sensor element (a vibrator element) related to the second embodiment of the invention.

The sensor element related to the present embodiment is the same as the sensor element related to the above-mentioned first embodiment, except that the configurations concerning the wiring of the drive unit and the detection unit differ.

In addition, in the following description, a difference between the sensor element of the second embodiment and the above-mentioned embodiment will be mainly described, and the description of the same matters will be omitted. Furthermore, in FIGS. 8A and 8B, the same configurations as those of the above-mentioned embodiment are denoted by the same reference numerals. Furthermore, FIG. 8A is across-sectional view corresponding to FIG. 5A, and FIG. 8B is a cross-sectional view corresponding to FIG. 5B.

As shown in FIGS. 8A and 8B, the sensor element of the present embodiment has a drive unit 51A and a detection unit 55A provided in the vibrating arm 22.

As shown in FIG. 8A, the drive unit 51A (a first piezoelectric body element) has a first electrode layer 511A (a first lower electrode layer), a second electrode layer 513A (a first upper electrode layer) provided on a side opposite to the vibrating arm 22 with respect to the first electrode layer 511A, and a piezoelectric body layer 512A (a first piezoelectric body layer) provided between the first electrode layer 511A and the second electrode layer 513A.

Moreover, the wiring 62A is drawn to the second electrode layer 513A of the drive unit 51A.

The wiring 62A has a portion that is provided along a side surface of the piezoelectric body layer 512A.

Furthermore, an insulator layer 61A is provided between the side surfaces of the piezoelectric body layer 512A and the first electrode layer 511A and the wiring 62A.

In the present embodiment, the side surface of the piezoelectric body layer 512A is inclined so as to alleviate the step due to the piezoelectric body layer 512A with respect to a main surface of the first electrode layer 511A. Thereby, it is possible to prevent a disconnection of the wiring 62A caused by the step due to the piezoelectric body layer 512A, and the damage of the insulator layer 61A. Furthermore, film forming properties when forming the wiring 62A and the insulating layer 61A can be increased.

As shown in FIG. 8B, the detection unit 55A (a first piezoelectric body element) has a first electrode layer 551A (a first lower electrode layer), a second electrode layer 553A (a first upper electrode layer) provided on a side opposite to the vibrating arm 22 with respect to the first electrode layer 551A, and a piezoelectric body layer 552A (a first piezoelectric body layer) provided between the first electrode layer 551A and the second electrode layer 553A.

Moreover, a wiring 64A is drawn to the second electrode layer 553A of the detection unit 55A.

The wiring 64A has a portion that is provided along a side surface of the piezoelectric body layer 552A.

Furthermore, an insulator layer 63A is provided between the side surfaces of the piezoelectric body layer 552A and the first electrode layer 551A and the wiring 64A.

In the present embodiment, the side surface of the piezoelectric body layer 552A is inclined so as to alleviate the step due to the piezoelectric body layer 552A with respect to a main surface of the first electrode layer 511A. Thereby, it is possible to prevent a disconnection of the wiring 64A caused by the step due to the piezoelectric body layer 552A, and the damage of the insulator layer 63A. Furthermore, film forming properties when forming the wiring 64A and the insulating layer 63A can be increased.

It is possible to perform the bridge wiring to the upper electrode layer on the piezoelectric body layer by the sensor element related to the above-mentioned second embodiment, while preventing the adverse effects to the characteristics of the sensor element.

### Third Embodiment

Next, a third embodiment of the invention will be described.

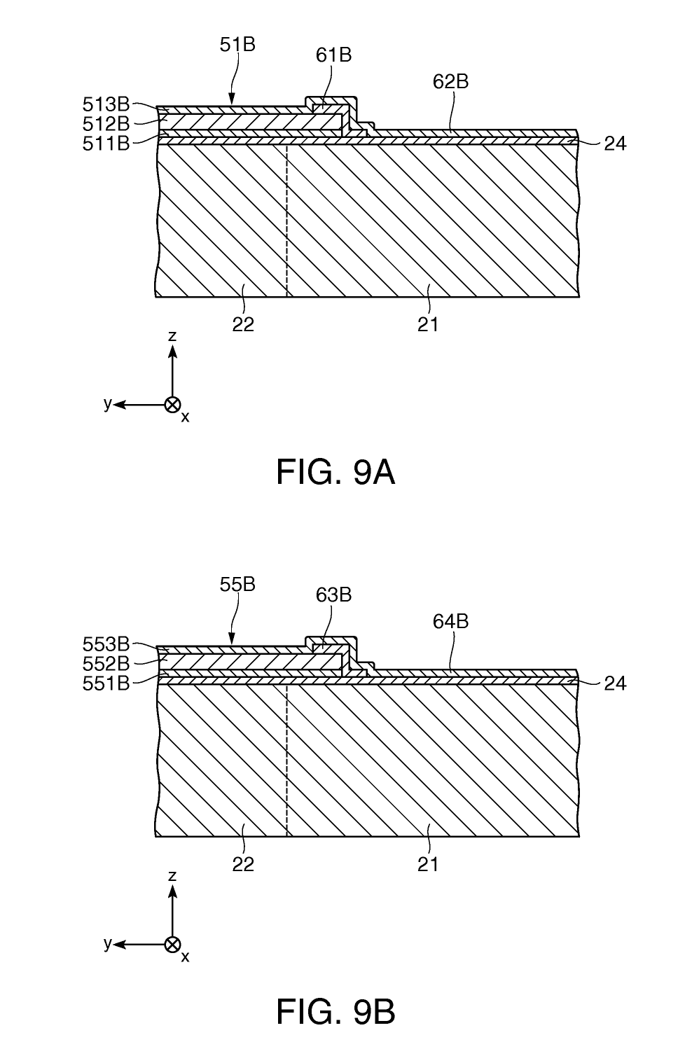

FIGS. 9A and 9B are diagrams for illustrating a sensor element (a vibrator element) related to the third embodiment of the invention.

The sensor element related to the present embodiment is the same as the sensor element related to the above-mentioned first embodiment, except for the configuration concerning the wirings of the drive unit and the detection unit.

In addition, in the following description, a difference between the sensor element of the third embodiment and the above-mentioned embodiments will be mainly described, and the description of the same matters will be omitted. Furthermore, in FIGS. 9A and 9B, the same configurations as those of the above-mentioned embodiments are denoted by the same reference numerals. Furthermore, FIG. 9A is a cross-sectional view corresponding to FIG. 5A, and FIG. 9B is a cross-sectional view corresponding to FIG. 5B.

As shown in FIGS. 9A and 9B, the sensor element of the present embodiment has a drive unit 51B and a detection unit 55B provided in the vibrating arm 22.

As shown in FIG. 9A, the drive unit 51B (a first piezoelectric body element) has a first electrode layer 511B (a first lower electrode layer), a second electrode layer 513B (a first upper electrode layer) provided on a side opposite to the vibrating arm 22 with respect to the first electrode layer 511B, and a piezoelectric body layer 512B (a first piezoelectric body layer) provided between the first electrode layer 511B and the second electrode layer 513B.

Moreover, a wiring 62B is drawn to the second electrode layer 513B of the drive unit 51B.

The wiring 62B has a portion that is provided along a side surface of the piezoelectric body layer 512B.

Furthermore, an insulator layer 61B is provided between the side surfaces of the piezoelectric body layer 512B and the first electrode layer 511B and the wiring 62B.

In the present embodiment, the insulator layer 61B has a portion provided on the second electrode layer 513B side with respect to the piezoelectric body layer 512B, and the second electrode layer 513B is not present between the portion and the piezoelectric body layer 512B. Thereby, when manufacturing the sensor element, after forming the insulator layer 61B, the second electrode layer 513B and the wiring 62B can be formed together. For that reason, the manufacturing process of the sensor element can be simplified.

As shown in FIG. 9B, the detection unit 55B (a first piezoelectric body element) has a first electrode layer 551B (a first lower electrode layer), a second electrode layer 553B (a first upper electrode layer) provided on a side opposite to the vibrating arm 22 with respect to the first electrode layer 551B, and a piezoelectric body layer 552B (a first piezoelectric body layer) provided between the first electrode layer 551B and the second electrode layer 553B.

Moreover, a wiring 64B is drawn to the second electrode layer 553B of the detection unit 55B.

The wiring 64B has a portion that is provided along a side surface of the piezoelectric body layer 552B.

Furthermore, an insulator layer 63B is provided between the side surfaces of the piezoelectric body layer 552B and the first electrode layer 551B and the wiring 64B.

In the present embodiment, the insulator layer 63B has a portion that is provided on the second electrode layer 553B side with respect to the piezoelectric body layer 552B, and the second electrode layer 553B is not present between the portion and the piezoelectric body layer 552B. Thereby, when manufacturing the sensor element, after forming the insulator layer 63B, the second electrode layer 553B and the wiring 64B can be formed together. For that reason, the manufacturing process of the sensor element can be simplified.

With the sensor element related to the above-mentioned third embodiment, it is possible to perform the bridge wiring to the upper electrode layer on the piezoelectric body layer, while preventing the adverse effects to the characteristics of the sensor element.

### Fourth Embodiment

Next, a fourth embodiment of the invention will be described.

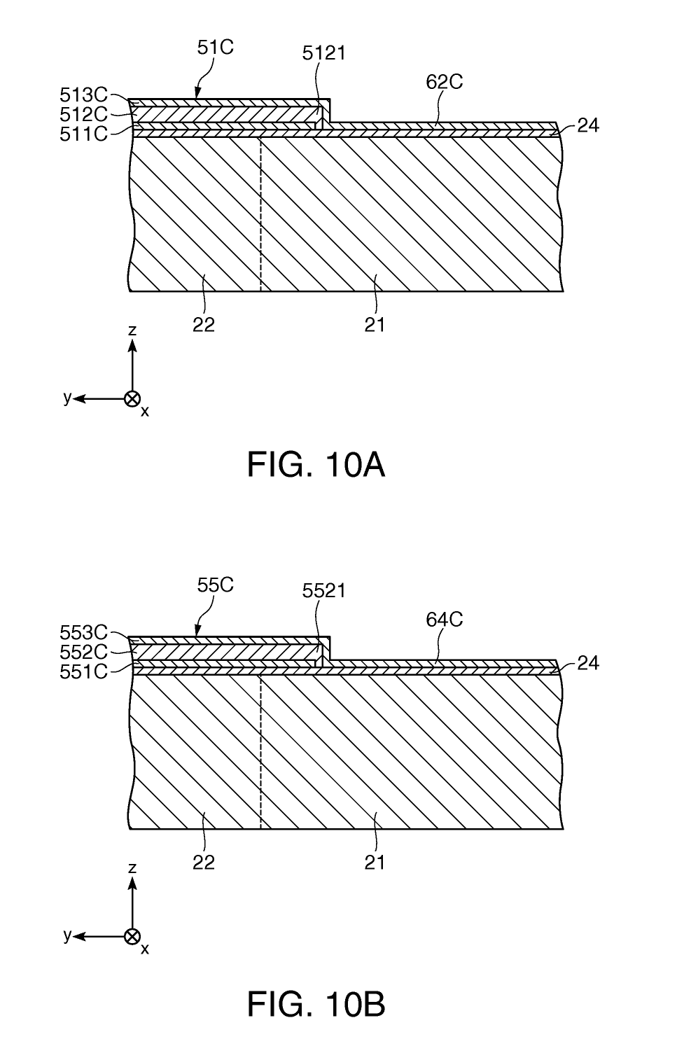

FIGS. 10A and 10B are diagrams for illustrating a sensor element (a vibrator element) related to the fourth embodiment of the invention.

The sensor element related to the present embodiment is the same as the sensor element related to the above-mentioned first embodiment except for the configuration concerning the wirings of the drive unit and the detection unit.

In addition, in the following description, a difference between the sensor element of the fourth embodiment and the above-mentioned embodiments will be mainly described, and the description of the same matters will be omitted. Furthermore, in FIGS. 10A and 10B, the same configurations as those of the above-mentioned embodiments are denoted by the same reference numerals. Furthermore, FIG. 10A is a cross-sectional view corresponding to FIG. 5A, and FIG. 10B is a cross-sectional view corresponding to FIG. 5B.

As shown in FIGS. 10A and 10B, the sensor element of the present embodiment has a drive unit 51C and a detection unit 55C provided in the vibrating arm 22.

As shown in FIG. 10A, the drive unit 51C has a first electrode layer 511C (a first lower electrode layer), a second electrode layer 513C (a first upper electrode layer) provided on a side opposite to the vibrating arm 22 with respect to the first electrode layer 511C, and a piezoelectric body layer 512C (a first piezoelectric body layer) provided between the first electrode layer 511C and the second electrode layer 513C.

Moreover, a wiring 62C is drawn to the second electrode layer 513C of the drive unit 51C.

The wiring 62C has a portion that is provided along the side surface of the piezoelectric body layer 512C.

The piezoelectric body layer 512C is formed so that a portion 5121 between the wiring 62C and the first electrode layer 511C covers the side surface of the first electrode layer 511C. Thereby, it is possible to prevent a short circuit between the wiring 62C and the first electrode layer 511C by the piezoelectric body layer 512C. For that reason, there is no need to separately provide an insulator layer for preventing a short circuit, and the manufacturing process can be simplified.

As shown in FIG. 10B, the detection unit 55C has a first electrode layer 551C (a first lower electrode layer), a second electrode layer 553C (a first upper electrode layer) provided on a side opposite to the vibrating arm 22 with respect to the first electrode layer 551C, and a piezoelectric body layer 552C (a first piezoelectric body layer) provided between the first electrode layer 551C and the second electrode layer 553C.

Moreover, the wiring 64C is drawn to the second electrode layer 553C of the detection unit 55C.

The wiring 64C has a portion that is provided along a side surface of the piezoelectric body layer 552C.

The piezoelectric body layer 552C is formed so that a portion 5521 between the wiring 64C and the first electrode layer 551C covers the side surface of the first electrode layer 551C. Thereby, it is possible to prevent a short circuit between the wiring 64C and the first electrode layer 551C by the piezoelectric body layer 552C. For that reason, there is no need to separately provide an insulator layer for preventing a short circuit, and the manufacturing process can be simplified.

With the sensor element related to the above-mentioned fourth embodiment, the sensor element can be manufactured at a high yield, and superior reliability can be exhibited.

### Fifth Embodiment

Next, a fifth embodiment of the invention will be described.

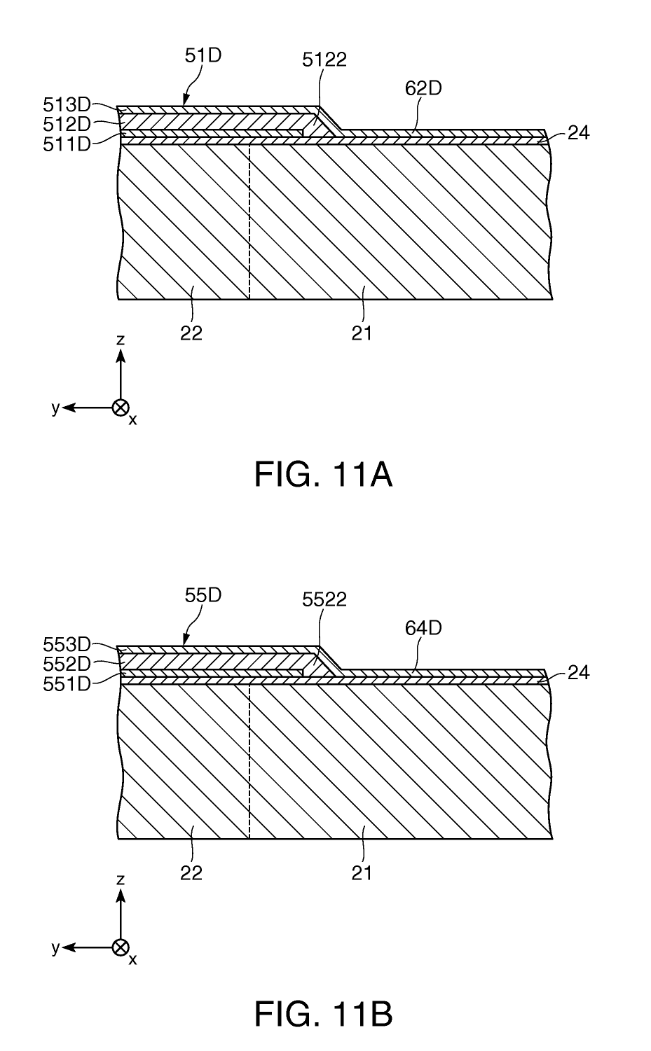

FIGS. 11A and 11B are diagrams for illustrating a sensor element (a vibrator element) related to the fifth embodiment of the invention.

The sensor element related to the present embodiment is the same as the sensor element 2 related to the above-mentioned first embodiment except for the configuration concerning the wirings of the drive unit and the detection unit.

In addition, in the following description, a difference between the sensor element of the fifth embodiment and the above-mentioned embodiments will be mainly described, and the description of the same matters will be omitted. Furthermore, in FIGS. 11A and 11B, the same configurations as those of the above-mentioned embodiments are denoted by the same reference numerals. Furthermore, FIG. 11A is a cross-sectional view corresponding to FIG. 5A, and FIG. 11B is a cross-sectional view corresponding to FIG. 5B.

As shown in FIGS. 11A and 11B, the sensor element of the present embodiment has a drive unit 51D and a detection unit 55D provided in the vibrating arm 22.

As shown in FIG. 11A, the drive unit 51D has a first electrode layer 511D (a first lower electrode layer), a second electrode layer 513D (a first upper electrode layer) provided on a side opposite to the vibrating arm 22 with respect to the first electrode layer 511D, and a piezoelectric body layer 512D (a first piezoelectric body layer) provided between the first electrode layer 511D and the second electrode layer 513D.

Moreover, a wiring 62D is drawn to the second electrode layer 513D of the drive unit 51D.

The wiring 62D has a portion that is provided along the side surface of the piezoelectric body layer 512D.

The piezoelectric body layer 512D is formed so that a portion 5122 between the wiring 62D and the first electrode layer 511D covers the side surface of the first electrode layer 511D. Thereby, it is possible to prevent a short circuit between the wiring 62D and the first electrode layer 511D by the piezoelectric body layer 512D. For that reason, there is no need to separately provide an insulator layer for preventing a short circuit, and the manufacturing process can be simplified.

Furthermore, the side surface of the portion 5122 of the piezoelectric body layer 512D is inclined so as to alleviate the step due to the piezoelectric body layer 512D. Thereby, it is possible to prevent a disconnection of the wiring 62D caused by the step due to the piezoelectric body layer 512D. Furthermore, film forming properties when forming the wiring 62D can be increased.

As shown in FIG. 11B, the detection unit 55D has a first electrode layer 551D (a first lower electrode layer), a second electrode layer 553D (a first upper electrode layer) provided on a side opposite to the vibrating arm 22 with respect to the first electrode layer 551D, and a piezoelectric body layer 552D (a first piezoelectric body layer) provided between the first electrode layer 551D and the second electrode layer 553D.

Moreover, a wiring 64D is drawn to the second electrode layer 553D of the detection unit 55D.

The wiring 64D has a portion that is provided along a side surface of the piezoelectric body layer 552D.

The piezoelectric body layer 552D is formed so that a portion 5522 between the wiring 64D and the first electrode layer 551D covers the side surface of the first electrode layer 551D. Thereby, it is possible to prevent a short circuit between the wiring 64D and the first electrode layer 551D by the piezoelectric body layer 552D. For that reason, there is no need to separately provide an insulator layer for preventing a short circuit, and the manufacturing process can be simplified.

Furthermore, the side surface of the portion 5522 of the piezoelectric body layer 552D is inclined so as to alleviate the step due to the piezoelectric body layer 552D. Thereby, it is possible to prevent a disconnection of the wiring 64D caused by the step due to the piezoelectric body layer 552D. Furthermore, film forming properties when forming the wiring 64D can be increased.

With the sensor element related to the above-mentioned fifth embodiment, the sensor element can be manufactured at a high yield, and superior reliability can be exhibited.

The sensor device of each embodiment as mentioned above can be incorporated into various electronic apparatuses and can be used.

According to such electronic apparatuses, superior reliability can be obtained.

### Sixth Embodiment

Next, a sixth embodiment of the invention will be described.

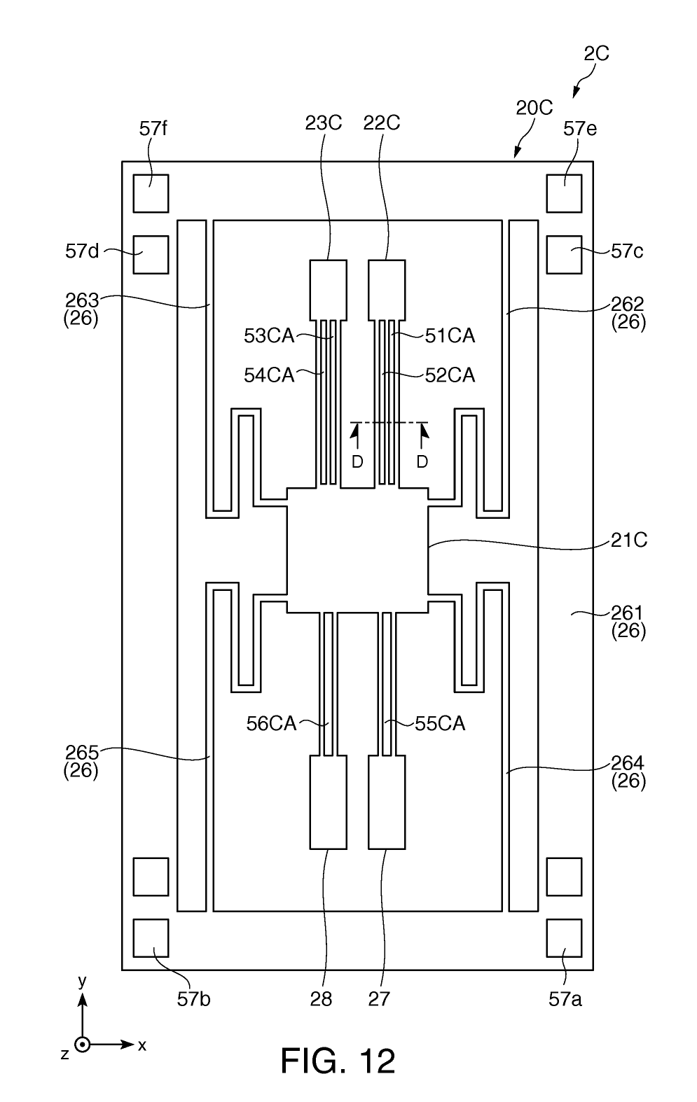

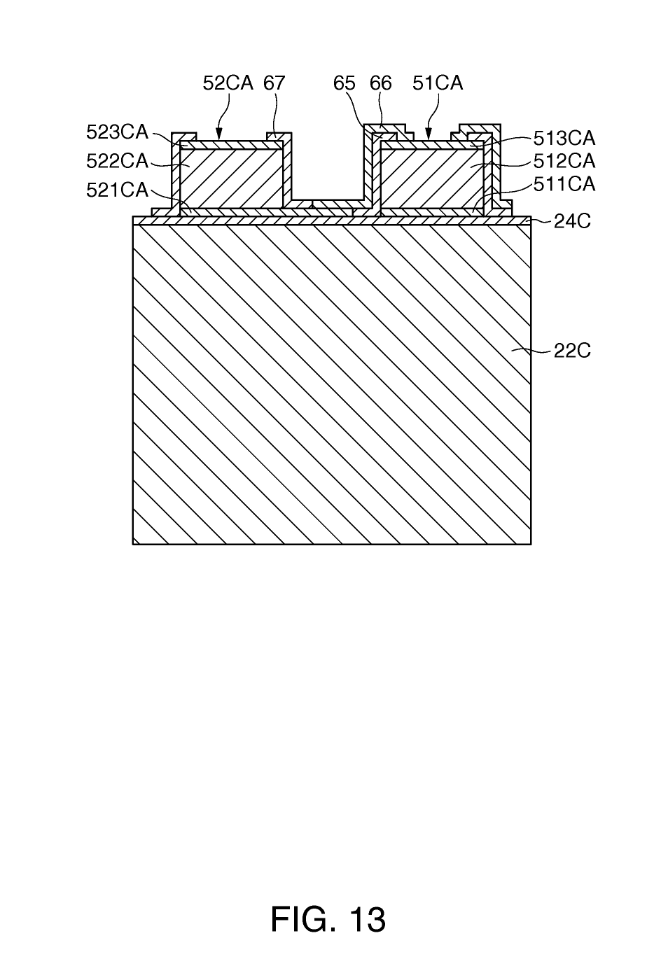

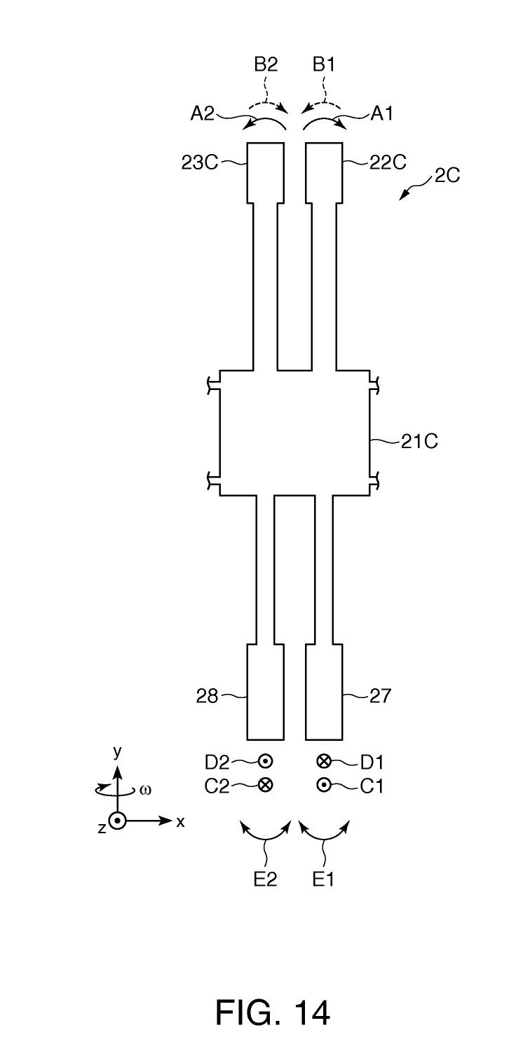

FIG. 12 is a plan view that shows a sensor element (a vibrator element) related to the sixth embodiment of the invention, FIG. 13 is a cross-sectional view of a line D-D in FIG. 12, and FIG. 14 is a diagram for illustrating the operation of the sensor element shown in FIG. 12.

Hereinafter, a difference between a sensor device of the sixth embodiment and the above-mentioned embodiments will be mainly described, and the description of the same matters will be omitted.

The sensor element related to the sixth embodiment of the invention is a so-called H type sensor element.

As shown in FIG. 12, a sensor element 2C of the present embodiment has a vibrating body 20C, drive units 51CA to 54CA provided on the vibrating body 20C, detection units 55CA and 56CA, and terminals 57a to 57f.

The vibrating body 20C has a so-called H type structure.

The vibrating body 20C has a base portion 21C, a pair of driving vibrating arms 22C and 23C, a pair of detecting vibrating arms 27 and 28, and a support unit 26.

The base portion 21C is supported by the support unit 26.

The support unit 26 has a frame-like fixing portion 261 fixed to a package (not shown), and four beam portions 262, 263, 264 and 265 that connect the fixing portion 261 with the base portion 21C.

The driving vibrating arms 22C and 23C each extend in the y axis direction (+y direction side) from the base portion 21C.

The detecting vibrating arms 27 and 28 each extend in the y axis direction (−y direction side) from the base portion 21C.

Such a vibrating body 20C can be formed by the use of the same material as the vibrating body 20 of the above-mentioned first embodiment.

A pair of drive units 51CA and 52CA is provided on the driving vibrating arm 22C of the vibrating body 20C configured in this manner. Similarly, a pair of drive units 53CA and 54CA is provided on the driving vibrating arm 23C.

Furthermore, the detection unit 55CA is provided on the detecting vibrating arm 27. Similarly, the detection unit 56CA is provided on the detecting vibrating arm 28.

The pair of drive units 51CA and 52CA is a piezoelectric body element that bends and vibrates the driving vibrating arm 22C in the x axis direction, respectively. Similarly, the pair of drive units 53CA and 54CA is a piezoelectric element that bends and vibrates the driving arm 23C in the x axis direction, respectively.

Herein, the pair of drive units 51CA and 52CA will be described in detail. In addition, since the drive units 53CA and 54CA are the same as the drive units 51CA and 52CA, the description thereof will be omitted.

As shown in FIG. 13, the drive unit 51CA (a first piezoelectric body element) has a first electrode layer 511CA (a first lower electrode layer), a second electrode layer 513CA (a first upper electrode layer) provided on a side opposite to the driving vibrating arm 22C with respect to the first electrode layer 511CA, and a piezoelectric body layer 512CA (a first piezoelectric body layer) provided between the first electrode layer 511CA and the second electrode layer 513CA. In other words, the drive unit 51CA is configured so that the first electrode layer 511CA, the piezoelectric body layer (the piezoelectric thin film) 512CA, and the second electrode layer 513CA are stacked on the driving vibrating arm 22C in this order.

Similarly, the drive unit 52CA (a second piezoelectric body element) is configured so that a first electrode layer 521CA (a second lower electrode), a piezoelectric body layer (a second piezoelectric thin film) 522CA, and a second electrode layer 523CA (a second upper electrode layer) are stacked on the driving vibrating arm 22C in this order.

Furthermore, a wiring 66 electrically connected to the first electrode layer 521CA of the drive unit 52CA is drawn to the second electrode layer 513CA of the drive unit 51CA.

The wiring 66 has a portion that is provided along the side surface of the drive unit 52CA side of the piezoelectric body layer 512CA.

Furthermore, the insulator layer 65 is provided between the side surfaces of the piezoelectric body layer 512CA and the first electrode layer 511CA and the wiring 66.

In this manner, the second electrode layer 513CA of one drive unit 51CA is electrically connected to the first electrode layer 521CA of the other drive unit 52CA via the wiring 66, whereby the parasitic capacitance between the wiring 66 and the first electrode layer 511CA can be reduced. Thus, the drop of the drive force due to the wiring 66 can be prevented.

Furthermore, the insulator layer 65 has a portion that is provided on the second electrode layer 513CA side with respect to the piezoelectric body layer 512CA. Moreover, a part of the second electrode layer 513CA is interposed between the portion and the piezoelectric body layer 512CA. Thereby, the electrode area of the second electrode layer 513CA can be increased. For that reason, the superior electric field efficiency of the drive unit 51CA can be obtained.

Furthermore, the insulator layer 67 is provided so as to cover the side surfaces of the first electrode layer 521CA, the piezoelectric body layer 522CA and the second electrode layer 523CA of the drive unit 52CA. Thereby, reliability of the drive unit 52CA can be increased. The insulator layer 67 can be formed together with the above-mentioned insulator layer 65.

The drive units 51CA to 54CA are electrically connected to the terminals 57a and 57b provided in the fixing portion 261 via a wiring (not shown).

Meanwhile, the detection unit 55CA is a piezoelectric body element that detects the bending vibration of the detecting vibrating arm 27 in the z axis direction. Similarly, the detection unit 56CA is a piezoelectric body element that detects the bending vibration of the detecting vibrating arm 28 in the z axis direction.

The detection units 55CA and 56CA are configured similarly with the detection units 55 and 56 of the above-mentioned first embodiment.

The detection unit 55CA is electrically connected to the terminals 57c and 57d provided in the fixing portion 261 via a wiring (not shown). Similarly, the detection unit 56CA is electrically connected to the terminals 57e and 57f provided in the fixing portion 261 via a wiring (not shown).

In the sensor element 2C configured in this manner, the drive signal is applied between the terminal 57a and the terminal 57b, whereby the driving vibrating arm 22C and the driving vibrating arm 23C are subjected to the bending vibration (the driving vibration) so as to approach and be separated from each other, as shown in FIG. 14. That is, a state where the driving vibrating arm 22C is bent in a direction of an arrow A1 shown in FIG. 14 and the driving vibrating arm 23C is bent in a direction of an arrow A2 shown in FIG. 14, and a state where the driving vibrating arm 22C is bent in a direction of an arrow B1 shown in FIG. 14 and the driving vibrating arm 23C is bent in a direction of an arrow B2 shown in FIG. 14 are alternately repeated.

In this manner, when an angular velocity W around the y axis is applied to the sensor element 2C in the state of performing the driving vibration of the driving vibrating arms 22C and 23C, the driving vibrating arms 22C and 23C are subjected to the bending vibration to the opposite sides in the z axis direction by Coriolis force. Along with this, the detecting vibrating arms 27 and 28 are subjected to the bending vibration (the detecting vibration) to the opposite sides in the z axis direction. That is, a state where the detecting vibrating arm 27 is bent in a direction of an arrow C1 shown in FIG. 14 and the detecting vibrating arm 28 is bent in a direction of an arrow C2 shown in FIG. 14, and a state where the detecting vibrating arm 27 is bent in a direction of an arrow D1 shown in FIG. 14 and the detecting vibrating arm 28 is bent in a direction of an arrow D2 shown in FIG. 14 are alternately repeated.

By detecting the electric charge generated in the detection units 55CA and 56CA by the detecting vibration of the detecting vibrating arms 27 and 28, the angular velocity ω applied to the sensor element 2C can be obtained.

With the sensor element 2C related to the sixth embodiment as mentioned above, the bridge wiring to the upper electrode layer on the piezoelectric body layer can be performed, while preventing the adverse effects to the characteristics of the sensor element 2C.

### Seventh Embodiment

Next, a seventh embodiment of the invention will be described.

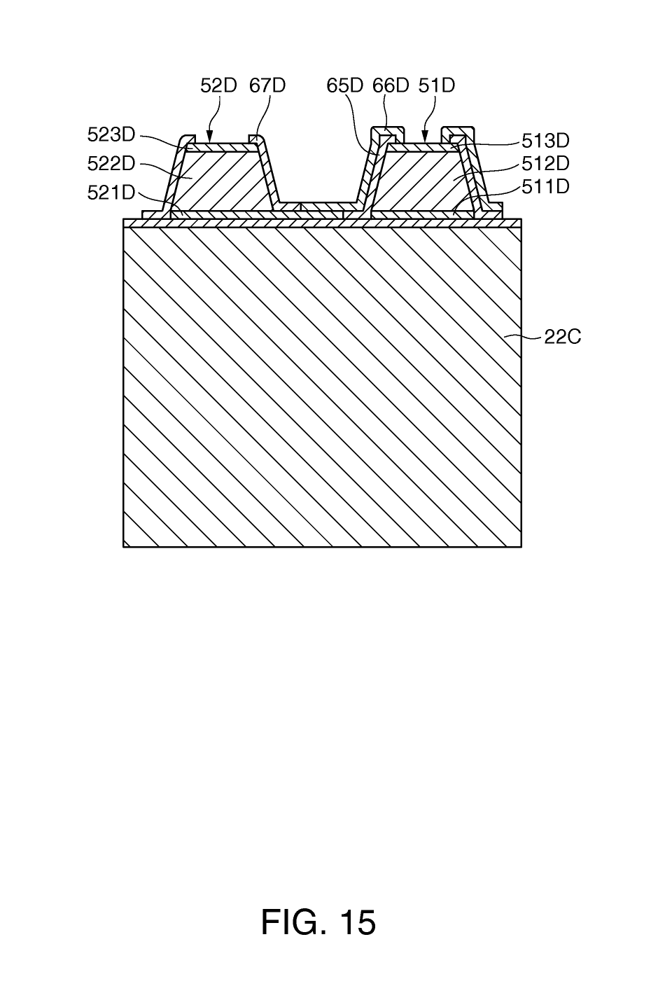

FIG. 15 is a diagram for illustrating a sensor element related to the seventh embodiment of the invention.

The sensor element related to the embodiment is the same as the sensor element 2C related to the above-mentioned sixth embodiment except for the configuration concerning the wiring of the drive unit.

In addition, in the following description, a difference between the sensor element of the seventh embodiment and the above-mentioned embodiments will be mainly described, and the description of the same matters will be omitted. Furthermore, in FIG. 15, the same configurations as those of the above-mentioned embodiments are denoted by the same reference numerals. Furthermore, FIG. 15 is across-sectional view corresponding to FIG. 13.

As shown in FIG. 15, the sensor element of the present embodiment has a pair of drive units 51D and 52D provided in the driving vibrating arm 22C.

The drive unit 51D (a first piezoelectric body element) has a first electrode layer 511D (a first lower electrode layer), a second electrode layer 513D (a first upper electrode layer) provided on a side opposite to the driving vibrating arm 22C with respect to the first electrode layer 511D, and a piezoelectric body layer 512D (a first piezoelectric body layer) provided between the first electrode layer 511D and the second electrode layer 513D.

Similarly, the drive unit 52D (a second piezoelectric body element) has a first electrode layer 521D (a second lower electrode layer), a second electrode layer 523D (a second upper electrode layer) provided on a side opposite to the driving vibrating arm 22C with respect to the first electrode layer 521D, and a piezoelectric body layer 522D (a second piezoelectric body layer) provided between the first electrode layer 521D and the second electrode layer 523D.

Moreover, a wiring 66D electrically connected to the first electrode layer 521D of the drive unit 52D is drawn to the second electrode layer 513D of the drive unit 51D.

The wiring 66D has a portion that is provided along a side surface of the piezoelectric body layer 512D.

Furthermore, an insulator layer 65D is provided between the side surfaces of the piezoelectric body layer 512D and the first electrode layer 511D and the wiring 66D.

In the present embodiment, the side surface of the piezoelectric body layer 512D is inclined so as to alleviate the step due to the piezoelectric body layer 512D. Thereby, it is possible to prevent a disconnection of the wiring 66D caused by the step due to the piezoelectric body layer 512D, and the damage of the insulator layer 65D. Furthermore, film forming properties when forming the wiring 66D and the insulating layer 65D can be increased.

It is possible to perform the bridge wiring to the upper electrode layer on the piezoelectric body layer by the sensor element related to the above-mentioned seventh embodiment, while preventing the adverse effects to the characteristics of the sensor element.

### Eighth Embodiment

Next, an eighth embodiment of the invention will be described.

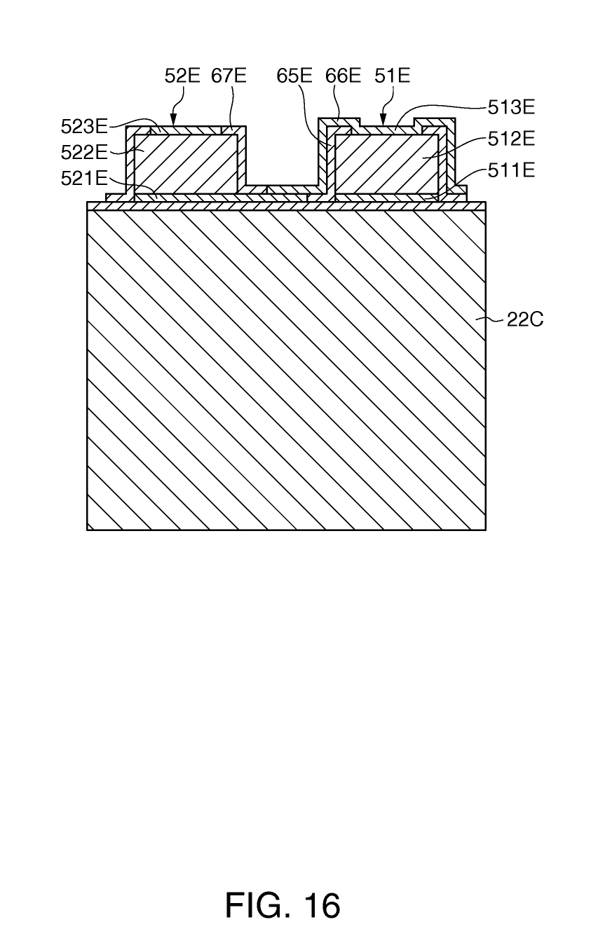

FIG. 16 is a diagram for illustrating a sensor element related to the eighth embodiment of the invention.

The sensor element related to the embodiment is the same as the sensor element 2C related to the above-mentioned sixth embodiment except for the configuration concerning the wiring of the drive unit.

In addition, in the following description, a difference between the sensor element of the eighth embodiment and the above-mentioned embodiments will be mainly described, and the description of the same matters will be omitted. Furthermore, in FIG. 16, the same configurations as those of the above-mentioned embodiments are denoted by the same reference numerals. Furthermore, FIG. 16 is a cross-sectional view corresponding to FIG. 13.

As shown in FIG. 16, the sensor element of the present embodiment has a pair of drive units 51E and 52E provided in the driving vibrating arm 22C.

The drive unit 51E (a first piezoelectric body element) has a first electrode layer 511E (a first lower electrode layer), a second electrode layer 513E (a first upper electrode layer) provided on a side opposite to the vibrating arm 22C with respect to the first electrode layer 511E, and a piezoelectric body layer 512E (a first piezoelectric body layer) provided between the first electrode layer 511E and the second electrode layer 513E.

Similarly, the drive unit 52E (a second piezoelectric body element) has a first electrode layer 521E (a second lower electrode layer), a second electrode layer 523E (a second upper electrode layer) provided on a side opposite to the vibrating arm 22C with respect to the first electrode layer 521E, and a piezoelectric body layer 522E (a second piezoelectric body layer) provided between the first electrode layer 521E and the second electrode layer 523E.

Moreover, a wiring 66E electrically connected to the first electrode layer 521E of the drive unit 52E is drawn to the second electrode layer 513E of the drive unit 51E.

The wiring 66E has a portion that is provided along a side surface of the piezoelectric body layer 512E.

Furthermore, an insulator layer 65E is provided between the side surfaces of the piezoelectric body layer 512E and the first electrode layer 511E and the wiring 66E.

In the present embodiment, the insulator layer 65E has a portion provided on the second electrode layer 513E side with respect to the piezoelectric body layer 512E, and the second electrode layer 513E is not present between the portion and the piezoelectric body layer 512E. Thereby, when manufacturing the sensor element, after forming the insulator layer 65E, the second electrode layer 513E and the wiring 66E can be formed together. For that reason, the manufacturing process of the sensor element can be simplified.

With the sensor element related to the above-mentioned eighth embodiment, it is possible to perform the bridge wiring to the upper electrode layer on the piezoelectric body layer, while preventing the adverse effects to the characteristics of the sensor element.

The sensor device (the vibration device) of each embodiment mentioned above can be incorporated into various electronic apparatuses and can be used.

According to such an electronic apparatus, superior reliability can be obtained.

### Electronic Apparatus

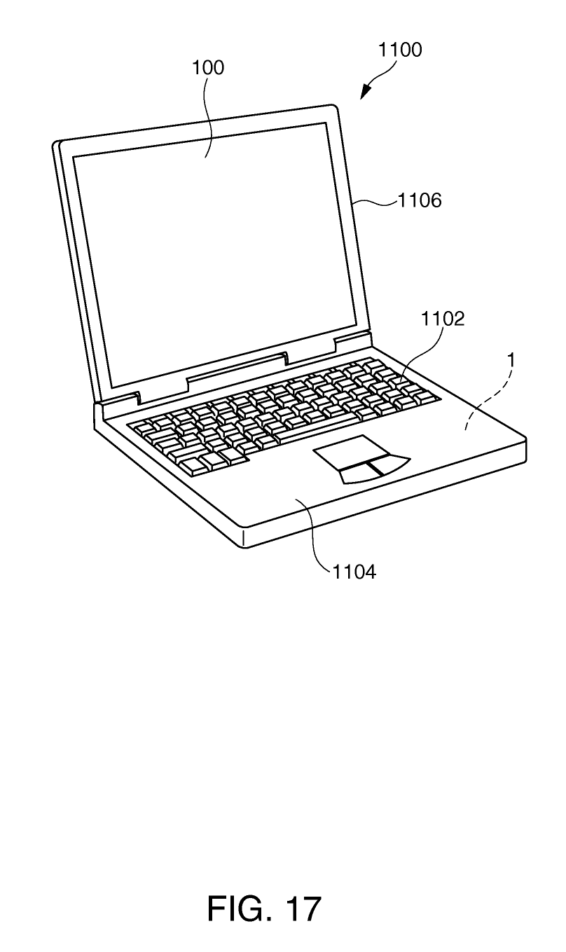

Herein, an example of the electronic apparatus of the invention will be described in detail, based on FIGS. 17 to 19.

FIG. 17 is a perspective view that shows a configuration of a mobile type (or a notebook type) personal computer to which the electronic apparatus of the invention is applied.

In FIG. 17, a personal computer 1100 is constituted by a main body portion 1104 including a keyboard 1102, and a display unit 1106 including a display portion 100, and the display unit 1106 is rotatably supported with respect to the main body portion 1104 via a hinge structure portion.

Such a personal computer 1100 is equipped with the above-mentioned sensor device 1 functioning as a gyro sensor.

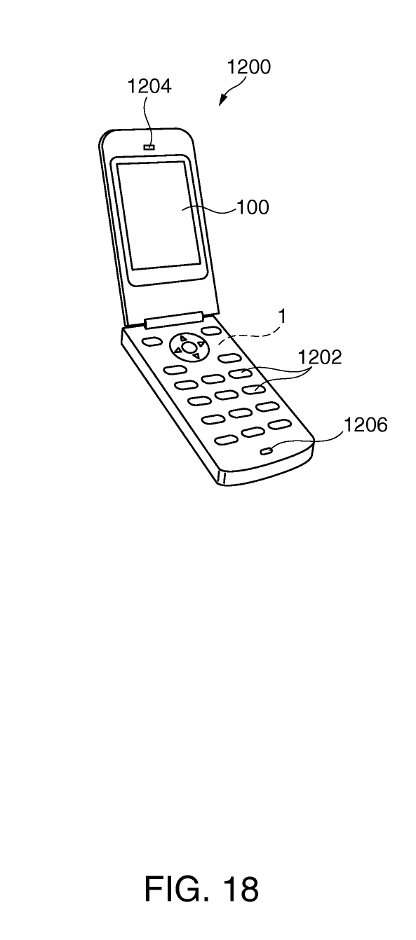

FIG. 18 is a perspective view that shows a configuration of a mobile phone (also including PHS) to which the electronic apparatus of the invention is applied.

In FIG. 18, a mobile phone 1200 includes a plurality of operation buttons 1202, an ear piece 1204, and a mouth piece 1206, and a display portion 100 is placed between the operation buttons 1202 and the ear piece 1204.

Such a mobile phone 1200 is equipped with the above-mentioned sensor device 1 functioning as the gyro sensor.

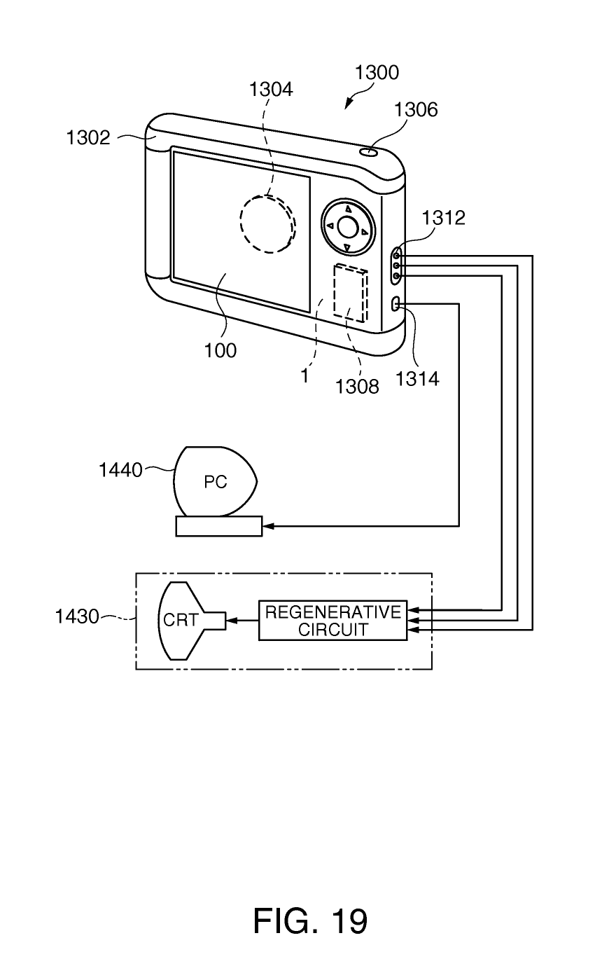

FIG. 19 is a perspective view that shows a configuration of a digital still camera to which the electronic apparatus of the invention is applied. In addition, in FIG. 19, the connection with an external apparatus is also simply shown.

Herein, a normal camera exposes silver halide photography to light by a photo image of a subject, and meanwhile, the digital still camera 1300 performs the photoelectric conversion of the optical image of the subject using an image pickup device such as CCD (Charge Coupled Device) to generate the image pickup signal (the image signal).

The display portion 100 is provided on the back surface of a case (a body) 1302 in the digital still camera 1300, the display is performed based on the image pickup signal using the CCD, and the display portion functions as a finder that displays the subject as an electronic image.

Furthermore, on a front side (a rear surface side in FIG. 19) of the case 1302, a light receiving unit 1304 including an optical lens (an image pickup optical system), a CCD or the like is provided.

When a photographer confirms the subject image displayed on the display portion and presses a shutter button 1306 down, the image pickup signal of the CCD at that time point is transmitted to and stored in a memory 1308.

Furthermore, in the digital still camera 1300, on the side surface of the case 1302, a video signal output terminal 1312 and an input and output terminal 1314 for data communication are provided. Moreover, as shown, a television monitor 1430 is connected to the video signal output terminal 1312, and a personal computer 1440 is connected to the input and output terminal 1314 for data communication, as needed, respectively. In addition, there is provided a configuration in which the image pickup signal stored in the memory 1308 is output to the television monitor 1430 and the personal computer 1440 by the predetermined operation.

The digital still camera 1300 is equipped with the above-mentioned sensor device 1 functioning as the gyro sensor.

In addition, the electronic apparatus of the invention can also be applied to, for example, a vehicle body posture detection device, a pointing device, a head mount display, an ink jet type discharge device (for example, an ink jet printer), a laptop type personal computer, a television, a video camera, a video tape recorder, a navigation device, a pager, an electronic organizer (also including a communication function), an electronic dictionary, an electronic calculator, an electronic game device, a game controller, a word processor, a workstation, a videophone, a television monitor for crime prevention, an electronic binoculars, a POS terminal, a medical device (for example, an electronic thermometer, a sphygmomanometer, a blood glucose monitoring system, an electrocardiogram measurement device, an ultrasonic diagnostic device, and an electronic endoscope), a fish finder, various measurement devices, meters (for example, meters of a vehicle, an airplane, and a vessel), a flight simulator or the like, depending on the kinds of the electronic devices, in addition to the personal computer (a mobile type personal computer) of FIG. 17, the mobile phone of FIG. 18, and the digital still camera of FIG. 19.

Although the vibrator element, a manufacturing method of the vibrator element, the vibration device and the electronic apparatus of the invention have been described based on the shown embodiments, the invention is not limited thereto.

Furthermore, in the vibrator element, the vibration device and the electronic apparatus of the embodiments of the invention, the configuration of each portion can be replaced with any configuration showing the same function, and any configuration can also be added.

Furthermore, the vibrator element, the vibration device and the electronic apparatus of the embodiments of the invention may be configured so that any configurations of each embodiment mentioned above are combined with each other.

Furthermore, in the manufacturing method of the vibrator element of the embodiment of the invention, any process may be added.

Furthermore, in the above-mentioned embodiments, although a case has been described as an example where the invention is applied to the sensor element of two tuning forks and the H type tuning fork, the invention can be applied to various sensor elements (the gyro element) such as a double T type, a triangular tuning fork, a sinking comb type, an orthogonal type, and a prism type.

Furthermore, when at least one vibrating arm is provided with the above-mentioned piezoelectric body element (the drive unit or the detection unit), the number of the vibrating arms may be one or three or more.

The entire disclosure of Japanese Patent Application Nos. 2012-089665, filed Apr. 10, 2012 and 2012-089667, filed Apr. 10, 2012 are expressly incorporated by reference herein.

What is claimed is:

1. A vibrator element comprising:
a base portion;
a vibrating arm extended from the base portion;
a first piezoelectric body element that is provided in the vibrating arm, and has a first lower electrode layer, a first upper electrode layer provided above a side opposite to the vibrating arm with respect to the first lower electrode layer, and a first piezoelectric body layer provided between the first lower electrode layer and the first upper electrode layer;
a wiring having a portion that is drawn from the first upper electrode layer and is provided along a side surface of the first piezoelectric body layer; and
a terminal that is provided in the base portion and is electrically connected to the first upper electrode layer via the wiring.

2. The vibrator element according to claim 1, further comprising:
an insulator layer that is provided between the side surfaces of the first piezoelectric body layer and the first lower electrode layer and the wiring, and is formed by a material that is different from the first piezoelectric body layer.

3. The vibrator element according to claim 2,
wherein, when a dielectric constant of the first piezoelectric body layer is assumed to be ∈p and a dielectric constant of the insulator layer is assumed to be ∈i, a relationship of ∈p>∈i is satisfied.

4. The vibrator element according to claim 2,
wherein the insulator layer has a portion that is provided on the first upper electrode layer side with respect to the first piezoelectric body layer, and
a part of the first upper electrode layer is interposed between the portion and the first piezoelectric body layer.

5. The vibrator element according to claim 2,
wherein the insulator layer has a portion that is provided on the first upper electrode layer side with respect to the first piezoelectric body layer, and
the first upper electrode layer is not present between the portion and the first piezoelectric body layer.

6. The vibrator element according to claim 2,
wherein a thickness of the insulator layer is thicker than that of the first lower electrode layer.

7. The vibrator element according to claim 1,
wherein the first piezoelectric body layer is provided so that a portion between the wiring and the first lower electrode layer covers the side surface of the first lower electrode layer.

8. The vibrator element according to claim 2,
wherein the side surface of the first piezoelectric body layer is inclined with respect to a main surface of the first lower electrode layer.

9. The vibrator element according to claim 1,
wherein the first upper electrode layer and the wiring are formed of the same material.

10. The vibrator element according to claim 1,
wherein the first upper electrode layer and the wiring are integrally formed.

11. The vibrator element according to claim 1, further comprising:
a second piezoelectric body element that is provided in the vibrating arm, and has a second lower electrode layer, a second upper electrode layer provided on a side opposite to the vibrating arm with respect to the second lower electrode layer, and a second piezoelectric body layer provided between the second lower electrode layer and the second upper electrode layer,
wherein the wiring is electrically connected to the second lower electrode layer.

12. A vibration device comprising the vibrator element according to claim 1.

13. An electronic apparatus comprising the vibrator element according to claim 1.
